(19) United States
(12) Patent Application Publication
(10) Pub. No.: US 2016/0111460 A1
(43) Pub. Date: Apr. 21, 2016

(54) BACK-LIT PHOTODETECTOR

(71) Applicant: ZENA TECHNOLOGIES, INC., CAMBRIDGE, MA (US)

(72) Inventor: Munib WOBER, Topsfield, MA (US)

(21) Appl. No.: 14/516,402

(22) Filed: Oct. 16, 2014

(51) Int. Cl. H01L 27/146; H01L 31/105

(52) U.S. Cl. CPC H01L 27/14605; H01L 27/14645; H01L 31/105

(57) ABSTRACT

Described herein are devices operable to detect various portions of radiation incident on a receiving area of the device, systems incorporating the same, methods of using and methods of manufacturing thereof. Such a device comprises a substrate; at least one first feature; and at least one second feature, both extending substantially perpendicularly from the substrate. The at least one first feature and the at least second feature are operable to selectively absorb various portions of the radiation defined by their respective ranges of wavelengths. The at least one first feature and the at least one second feature are positioned on the substrate such that at least 50% of the first portion and at least 50% of the second portion of the radiation incident on the receiving area is selectively absorbed by the at least one first feature and the at least one second feature, respectively.

### CROSS-REFERENCE TO RELATED APPLICATIONS

The disclosures of U.S. patent application Ser. No. 12/204,686, filed Sep. 4, 2008 (now U.S. Pat. No. 7,646,943), Ser. No. 12/648,942, filed Dec. 29, 2009 (now U.S. Pat. No. 8,229,255), Ser. No. 13/556,041, filed Jul. 23, 2012, Ser. No. 12/270,233, filed Nov. 13, 2008 (now U.S. Pat. No. 8,274,039), Ser. No. 13/925,429, filed Jun. 24, 2013, Ser. No. 13/570,027, filed Aug. 8, 2012 (now U.S. Pat. No. 8,471,190), Ser. No. 12/472,264, filed May 26, 2009 (now U.S. Pat. No. 8,269,985, Ser. No. 13/621,607, filed Sep. 17, 2012 (now U.S. Pat. No. 8,514,411), Ser. No. 13/971,523, filed Aug. 20, 2013 (now allowed), Ser. No. 12/472,271, filed May 26, 2009 (now abandoned), Ser. No. 12/478,598, filed Jun. 4, 2009 (now U.S. Pat. No. 8,546,742), Ser. No. 14/021,672, filed Sep. 9, 2013, Ser. No. 12/573,582, filed Oct. 5, 2009 (now allowed), Ser. No. 14/274,448, filed May 9, 2014, Ser. No. 12/575,221, filed Oct. 7, 2009 (now U.S. Pat. No. 8,384,007), Ser. No. 12/633,323, filed Dec. 8, 2009 (now U.S. Pat. No. 8,735,797), Ser. No. 14/068,864, filed Oct. 31, 2013, Ser. No. 14/281,108, filed May 19, 2014, Ser. No. 13/494,661, filed Jun. 12, 2012 (now U.S. Pat. No. 8,754,359), Ser. No. 12/633,318, filed Dec. 8, 2009 (now U.S. Pat. No. 8,519,379), Ser. No. 13/975,553, filed Aug. 26, 2013 (now U.S. Pat. No. 8,710,488), Ser. No. 12/633,313, filed Dec. 8, 2009, Ser. No. 12/633,305, filed Dec. 8, 2009 (now U.S. Pat. No. 8,299,472), Ser. No. 13/543,556, filed Jul. 6, 2012 (now allowed), Ser. No. 12/621,497, filed Nov. 19, 2009 (now abandoned), Ser. No. 12/633,297, filed Dec. 8, 2009, Ser. No. 12/982,269, filed Dec. 30, 2010, Ser. No. 12/966,573, filed Dec. 13, 2010, Ser. No. 12/967,880, filed Dec. 14, 2010 (now U.S. Pat. No. 8,748,799), Ser. No. 12/966,514, filed Dec. 13, 2010, Ser. No. 12/974,499, filed Dec. 21, 2010 (now U.S. Pat. No. 8,507,840), Ser. No. 12/966,535, filed Dec. 13, 2010, Ser. No. 12/910,664, filed Oct. 22, 2010, Ser. No. 12/945,492, filed Nov. 12, 2010, Ser. No. 13/047,392, filed Mar. 14, 2011 (now allowed), Ser. No. 13/048,635, filed Mar. 15, 2011 (now allowed), Ser. No. 13/106,851, filed May 12, 2011, Ser. No. 13/288,131, filed Nov. 3, 2011, Ser. No. 14/032,166, filed Sep. 19, 2013, Ser. No. 13/543,307, filed Jul. 6, 2012, Ser. No. 13/963,847, filed Aug. 9, 2013, Ser. No. 13/693,207, filed Dec. 4, 2012, 61/869,727, filed Aug. 25, 2013, Ser. No. 14/322,503, filed Jul. 2, 2014, and Ser. No. 14/311,954, filed Jun. 23, 2014, are each hereby incorporated by reference in their entirety.

### BACKGROUND

Semiconductors can have electric conductive behavior somewhere between that of a metal and an insulator. Semiconductor devices can display a range of properties such as passing current more easily in one direction than another, showing variable resistance, and sensitivity to light or heat. Because of these and other properties, a semiconductor can be used for, e.g., amplification, switching, and energy conversion. Current conduction in a semiconductor occurs through the movement of free electrons and “holes,” collectively known as charge carriers. The conductivity of a semiconductor can be modified by doping with impurities. A doped semiconductor is known as “p-type” if it contains mostly free holes, and a doped semiconductor is known as “n-type” if it contains mostly free electrons. A semiconductor can be doped under controlled conditions with respect to, e.g., the location and concentration of p- and n-type dopants.

Electromagnetic waves, including visible light, can be described in terms of their properties including, e.g., wavelength, polarization, or the like, or a combination thereof. The wavelength of a wave can be the spatial period of the wave—the distance over which the wave's shape repeats. The wavelength of visible light ranges from deep red, roughly 700 nm, to violet, roughly 400 nm. Polarization is a property of certain types of waves that describes the orientation of their oscillations. By convention, the polarization of light is described by specifying the orientation of the light's electric field at a point in space over one period of the oscillation. When light travels in free space, in most cases it propagates as a transverse wave, i.e. the polarization is perpendicular to the light's direction of travel (or propagation). In this case, the electric field can be oriented in a single direction (linear polarization), or it can rotate as the wave travels (circular or elliptical polarization). In the latter cases, the oscillations can rotate either towards the right or towards the left in the direction of travel. Depending on which rotation is present in a given wave it is called the wave's chirality or handedness. Polarization of fully polarized light can be represented by a Jones vector. The x and y components of the complex amplitude of the electric field of light travel along z-direction, Eₓ(t) and E_{y}(t), are represented as

$$( \begin{matrix}{E}_{x} ( t ) \\ {E}_{y} ( t )\end{matrix} ) = {E}_{0} ( \begin{matrix}{E}_{0 x} {e}^{i ( kz - ω t + {φ}_{x} )} \\ {E}_{0 y} {e}^{i ( kz - ω t + {φ}_{x} )}\end{matrix} ) = {E}_{0} {e}^{i ( kz - ω t )} ( \begin{matrix}{E}_{0 x} {e}^{i {φ}_{x}} \\ {E}_{0 y} {e}^{i {φ}_{y}}\end{matrix} ) \cdot ( \begin{matrix}{E}_{0 x} {e}^{i {φ}_{x}} \\ {E}_{0 y} {e}^{i {φ}_{y}}\end{matrix} )$$

is the Jones vector. Polarization of light with any polarization, including unpolarized, partially polarized, and fully polarized light, can be described by the Stokes parameters, which are four mutually independent parameters.

### SUMMARY

Described herein are a device operable to detect various portions of radiation incident on a receiving area of the device, a system incorporating the same, and methods of using and manufacturing thereof.

According to an embodiment, the radiation has linear polarization, circular or elliptical polarization. “Linear polarization” as used herein means the electric field of a wave (e.g., light) is confined to a given plane along the direction of propagation of the wave. “Circular polarization” as used herein means the electric field of a wave (e.g., light) does not change strength but only changes direction in a rotary type manner. “Elliptical polarization” as used herein means electric field of a wave (e.g., light) describes an ellipse in any fixed plane intersecting, and normal to, the direction of propagation of the wave. Information regarding the circular or elliptical polarization of radiation may be derived from information regarding the linear polarization of radiation. Circular polarization and elliptical polarization can be decomposed into linear polarizations. The disclosure is presented in connection with linear polarization of radiation.

According to an embodiment, a device can include at least one first feature extending substantially perpendicularly to a substrate, and at least one second feature extending substantially perpendicular to the substrate. The at least one first feature can be configured to selectively absorb a first portion of radiation within a first range of wavelength. The at least one second feature can be configured to selectively absorb a second portion of the radiation within a second range of wavelength. A first feature and a second feature can be different in, e.g., dimension, orientation. The first range and the second range can be different. The first feature and the second feature can be positioned in proximity, such that the at least one first feature can be operable to substantially absorb the first portion of the radiation in the receiving area of the device, and the at least one second feature can be operable to substantially absorb the second portion of the radiation in the receiving area of the device.

According to an embodiment, a device operable to detect at least a first portion and a second portion of radiation incident on a receiving area of the device, wherein the device comprises: at least one first feature, and at least one second feature. The at least one first feature extends substantially perpendicularly (e.g., the acute angel formed between the at least one first feature and the substrate being at least 70°, or at least 75°, or at least 80°, or at least) 85° from a substrate. The first feature is operable to selectively absorb the first portion of the radiation. The wavelengths of the first portion of the radiation are within a first range. The second feature extends substantially perpendicularly (e.g., the acute angel formed between the at least one first feature and the substrate being at least 70°, or at least 75°, or at least 80°, or at least 85°) from the substrate. The second feature is operable to selectively absorb the second portion of the radiation incident on the receiving area. The wavelengths of the second portion of the radiation are within a second range. The first range is different from the second range. The at least one first feature and the at least one second feature are positioned on the substrate such that at least a first percentage of the first portion of the radiation incident on the receiving area is absorbed by the at least one first feature, and at least a second percentage of the second portion of the radiation incident on the receiving area is absorbed by the at least one second feature. The first percentage or the second percentage is at least 50%, or at least 60%, or at least 70%.

According to an embodiment, the device further comprises at least one third feature. The third feature extends substantially perpendicularly (e.g., the acute angel formed between the at least one first feature and the substrate being at least 70°, or at least 75°, or at least 80°, or at least 85°) from the substrate. The third feature is operable to selectively absorb a third portion of the radiation. The wavelengths of the third portion of the radiation are within a third range. The third range can be different from the first range or the second range. The at least one third feature is positioned on the substrate such that at least a third percentage of the third portion of the radiation incident on the receiving area is selectively absorbed by the at least one third feature. The third percentage can be at least 50%, or at least 60%, or at least 70%. The third feature can react to the third portion of the radiation by converting at least a part of it to a third signal.

According to an embodiment, a device operable to detect at least a first portion and a second portion of radiation incident on a receiving area of the device, wherein the device comprises: at least one first feature, and at least one second feature. The first feature extends substantially perpendicularly (e.g., the acute angel formed between the at least one first feature and the substrate being at least 70°, or at least 75°, or at least 80°, or at least 85°) from a substrate. The first feature has a first surrounding area. The first feature is operable to selectively absorb at least 40%, or at least 50%, or at least 60%, or at least 70%, or at least 80% of the first portion of the radiation in the first surrounding area. The wavelengths of the first portion of the radiation are within a first range. The second feature extends substantially perpendicularly (e.g., the acute angel formed between the at least one first feature and the substrate being at least 70°, or at least 75°, or at least 80°, or at least 85°) from the substrate. The second feature has a second surrounding area. The second feature is operable to selectively absorb at least 40%, or at least 50%, or at least 60%, or at least 70%, or at least 80% of the second portion of the radiation in the second surrounding area. The wavelengths of the second portion of the radiation are within a second range. The first range is different from the second range. The at least one first feature and the at least one second feature are positioned on the substrate such that the first surrounding area and the second surrounding area overlap by at least 50%, or at least 60%, or at least 70% of the smaller of the first surrounding area and the second surrounding area.

According to an embodiment, the device further comprises at least one third feature. The third feature extends substantially perpendicularly (e.g., the acute angel formed between the at least one first feature and the substrate being at least 70°, or at least 75°, or at least 80°, or at least 85°) from the substrate. The third feature has a third surrounding area. The third feature is operable to selectively absorb at least 40%, or at least 50%, or at least 60%, or at least 70%, or at least 80% of a third portion of the radiation in the third surrounding area. The wavelengths of the third portion of the radiation are within a third range. The third range can be different from the first range or the second range. The third feature can react to the third portion of the radiation by converting at least a part of it to a third signal. The at least one first feature, the at least one second feature, and the at least one third feature are positioned on the substrate such that the first surrounding area, the second surrounding area, and the third surrounding area overlap by at least 50%, or at least 60%, or at least 70% of the smallest of the first surrounding area, the second surrounding area, and the third surrounding area.

The first range of wavelengths or the second range of wavelengths can be 450-495 nm, 495-570 nm, 570-590 nm, or 620-740 nm. The incident direction of the radiation is substantially perpendicular to the substrate.

According to an embodiment, at least one of the substrate, the first feature, or the second feature can comprise at least one material selected from the group consisting of silicon, germanium, boron, tellurium, selenium, tin, a III-V group compound semiconductor, and a II-VI group compound semiconductor, or the like, or a combination thereof. The first feature or the second feature can have a shape in a cross-section parallel to the substrate selected from the group consisting of a rectangle, an ellipse, convex-convex, concave-concave, plano-convex, and plano-concase.

According to an embodiment, a feature is operable to selectively absorb (e.g., at least 50%, or at least 60%, or at least 70%, or at least 80%, or at least 90% of) a specific portion of the radiation whose wavelengths are within a specific range. The feature can be configured to absorb little, e.g., no more than 50%, or no more than 40%, or no more than 30%, or no more than 20% of other portions of the radiation whose wavelengths are outside of the specific range.

According to an embodiment, the device includes multiple first features. At least two of the multiple first features can have a same orientation, or are parallel to each other. At least some adjacent first features of the multiple first features can be equally spaced from each other.

According to an embodiment, the device includes multiple second features. At least two of the multiple second features can have a same orientation, or are parallel to each other. At least some adjacent second features of the multiple second features can be equally spaced from each other.

According to an embodiment, a first feature has a first width and a first transverse dimension. The first width can be less than 200 nm. The first width can be approximately 100 nm, or approximately 80 nm, or approximately 60 nm. The first transverse dimension can be less than 200 nm. The first transverse dimension can be approximately 100 nm, or approximately 80 nm, or approximately 60 nm. The aspect ratio of the first feature can be less than 5, or less than 3.

According to an embodiment, a second feature has a second width and a second transverse dimension. The second width can be less than 200 nm. The second width can be approximately 100 nm, or approximately 80 nm, or approximately 60 nm. The second transverse dimension can be less than 200 nm. The second transverse dimension can be approximately 100 nm, or approximately 80 nm, or approximately 60 nm. The aspect ratio of the second feature can be less than 5, or less than 3.

According to an embodiment, the first feature can react to the first portion of the radiation by converting at least a part of it to a first signal. The second feature can react to the second portion of the radiation by converting at least a part of it to a second signal. The first signal or the second signal can be an electrical signal. The substrate of the device can comprise electrical components configured to detect the electrical signal.

According to an embodiment, at least a part of the substrate and the first feature form a monocrystal. According to an embodiment, at least a part of the substrate, the first feature and the second feature form a monocrystal. The first feature, the second feature and the substrate can comprise a p-i-n junction, a p-n junction, an intrinsic semiconductor, or a metal semiconductor. The substrate can comprise a first charge carrier collector configured to collect at least some charge carriers generated in the first feature by selectively absorbing the first portion of the radiation. The first charge carrier collector can be substantially parallel to the substrate. The first charge carrier collector can be slightly larger than, or substantially the same as, or slightly smaller than the cross-section of the first feature. The substrate can comprise a second charge carrier collector configured to collect at least some charge carriers generated in the second feature by selectively absorbing the second portion of the radiation. The second charge carrier collector can be substantially parallel to the substrate. The second charge carrier collector can be slightly larger than, or substantially the same as, or slightly smaller than the cross-section of the second feature. The first charge carrier collector and the second charge carrier collector can be substantially electrically insulated from each other. The first charge carrier collector and the second charge carrier collector can be a same charge carrier collector.

According to an embodiment, the first feature or the second feature comprises a p-i-n junction or forms a p-i-n junction with the substrate. The p-i-n junction is functional to convert at least a portion of the absorbed light to an electrical signal. An intrinsic semiconductor, also called an undoped semiconductor or i-type semiconductor, is a substantially pure semiconductor without any significant dopant species present. A lightly doped semiconductor is a doped semiconductor but not have a doping level as high as a heavily doped semiconductor. In a lightly doped semiconductor, dopant atoms create individual doping levels that can often be considered as localized states that can donate electrons or holes by thermal promotion (or an optical transition) to the conduction or valence bands respectively. At high enough impurity concentrations (i.e. heavily doped) the individual impurity atoms may become close enough neighbors that their doping levels merge into an impurity band and the behavior of such a system ceases to show the typical traits of a semiconductor. A heavily doped semiconductor is a semiconductor with such a high doping level that the semiconductor behaves electrically more like a metal than as a semiconductor. A heavily doped semiconductor exhibits an essentially linear positive thermal coefficient in its electrical resistivity. Dopant atoms in a heavily doped semiconductor have degenerate energy levels forming an impurity band.

According to an embodiment, the first feature or the second feature comprises an intrinsic semiconductor layer or a first lightly doped semiconductor layer, and a heavily doped semiconductor layer; and the substrate comprises a second lightly doped semiconductor layer; wherein the second lightly doped semiconductor layer is an opposite type from the heavily doped semiconductor layer; intrinsic semiconductor layer or a first lightly doped semiconductor layer is disposed on the second lightly doped semiconductor layer; and the heavily doped semiconductor layer is disposed on the intrinsic semiconductor layer or the first lightly doped semiconductor layer; and wherein the heavily doped semiconductor layer, the intrinsic layer or the first lightly doped semiconductor layer, and the second lightly doped semiconductor layer form a p-i-n junction.

According to an embodiment, the first feature or the second feature comprises a core of intrinsic semiconductor or lightly doped semiconductor, and a shell of heavily doped semiconductor; and the substrate comprises a lightly doped semiconductor layer; wherein the lightly doped semiconductor layer is an opposite type from the shell; the core is disposed on the lightly doped semiconductor layer; the shell is conformally disposed over the core; and wherein the shell, the core, and the lightly doped semiconductor layer form a p-i-n junction.

According to an embodiment, the first feature or the second feature comprises a core of lightly doped semiconductor, an intermediate shell of intrinsic semiconductor, and an outer shell of doped semiconductor; the intermediate shell is conformally disposed over the core; the outer shell is conformally disposed over the intermediate shell; the outer shell is of an opposite type from the core; and the outer shell, the intermediate shell, and the core form the p-i-n junction.

According to an embodiment, the first feature or the second feature comprises a first heavily doped semiconductor layer, a lightly doped semiconductor layer or intrinsic semiconductor layer, a second heavily doped layer; the first heavily doped semiconductor layer is disposed on the lightly doped semiconductor layer or intrinsic semiconductor layer; the lightly doped semiconductor layer or intrinsic semiconductor layer is disposed on the second heavily doped layer; the first heavily doped layer is of an opposite type from the second heavily doped layer; and the first heavily doped layer, the lightly doped semiconductor layer or intrinsic semiconductor layer, and the second heavily doped layer form the p-i-n junction.

According to an embodiment, the first feature or the second feature comprises a p-n junction formed by lightly or heavily doped semiconductor layers. According to an embodiment, the first feature or the second feature comprises an intrinsic semiconductor layer.

According to an embodiment, the substrate comprises electrical components configured to detect the electrical signal.

According to an embodiment, the device further comprises a first transparent electrode disposed on and electrically connected to the at least one first feature, and a second transparent electrode disposed on and electrically connected to the at least one second feature. The first and second transparent electrodes are separate or otherwise substantially electrically insulated from each other. The term “transparent” as used herein means a transmittance of at least 70%.

According to an embodiment, the device further comprises a cladding layer enclosing at least a part of the at least one first feature or the at least one second feature. The cladding layer can comprise at least one material selected from the group consisting of plasma enhanced Si₃N₄, plasma enhanced SiO₂, and SiO₂. The cladding layer can be configured to provide a graded refractive index such that a refractive index of the enclosed first feature or the enclosed second feature is higher than that of the cladding layer.

According to an embodiment, the device further comprises a reflective material deposited on areas of the substrate between the first and second features. A reflective material is a material with a reflectance of at least 50%.

According to an embodiment, a radiation detector array comprises any of the device above, and electronic circuitry functional to detect the electrical signal.

According to an embodiment, the electronic circuitry is further functional to calculate an interpolation of the features of the device, adjust a gain and/or calculate Stokes parameters.

According to an embodiment, a system comprises a device disclosed herein and electronic circuitry functional to detect an electrical signal. The electronic circuitry can be further functional to calculate an interpolation from the first feature or from the second feature, adjust a gain and/or calculate Stokes' parameters. The system can comprise at least one system selected from the group consisting of a camera, a video camera, a microscope, a satellite, an image sensor, a land vehicle (e.g., a car, a truck, a motorcycle), a water vehicle (e.g., a ship), an air vehicle (e.g., an unmanned air vehicle, an aircraft), a balloon, and an imaging device.

According to an embodiment, a method of detecting a first portion and a second portion of radiation, comprising obtaining a device disclosed herein, exposing the device to the radiation, and detecting the first portion and the second portion of the radiation. The wavelengths of the first portion of the radiation are within a first range, the wavelengths of the second portion of the radiation are within a second range, and the first range and the second range are different.

According to an embodiment, a method of fabricating a device disclosed herein comprises: lithography, ion implantation, annealing, evaporation, atomic layer deposition, chemical vapor deposition, dry etch, or a combination thereof.

### BRIEF DESCRIPTION OF THE DRAWINGS

FIG. 1A is a perspective view of the device according to one embodiment.

FIG. 1B is a cross-sectional view of the device illustrated in FIG. 1A.

FIG. 2A is a perspective view of the device according to one embodiment.

FIG. 2B is a cross-sectional view of the device illustrated in FIG. 2A.

FIG. 3A is a perspective view of the device according to one embodiment.

FIG. 3B is a cross-sectional view of the device illustrated in FIG. 3A.

FIG. 4 is a perspective view of the device according to one embodiment.

FIG. 5A is a cross-sectional view of the device according to one embodiment.

FIG. 5B is a top view of the device illustrated in FIG. 5A.

FIGS. 5C and 5D are cross-sectional views of the device illustrated in FIG. 5A.

FIG. 6A is a cross-sectional view of the device according to one embodiment.

FIG. 6B is a top view of the device illustrated in FIG. 6A.

FIG. 6C is a cross-sectional view of the device according to one embodiment.

FIG. 7 shows a top view of the device according to one embodiment.

FIGS. 8A-8C show exemplary features with various cross-sections according to some embodiments.

FIG. 9 shows a radiation detector array comprising a device disclosed herein.

FIG. 10 shows a schematic of a light detector apparatus in which a device disclosed herein is used as fore optics.

### DETAILED DESCRIPTION

The illustrated embodiments described in the detailed description, drawings, and Claims are not meant to be limiting. Other embodiments may be utilized, and other changes may be made, without departing from the spirit or scope of the subject matter presented here.

This disclosure is drawn to, among other things, methods of use, methods of fabrication, apparatuses, systems, and devices related to a device operable to detect and distinguish different portions of radiation incident on a receiving area of the device. The term “radiation” used herein refers to electromagnetic waves with any polarization, including unpolarized, partially polarized, and fully polarized electromagnetic waves. The radiation can include a first portion and a second portion. The wavelengths of the first portion of the radiation can be within a first range. The wavelengths of the second portion of the radiation can be within a second range. A portion of the radiation (e.g., a first portion or a second portion) can include a combination of waves linearly polarized on different directions, whose wavelengths are within a range. Merely by way of example, a portion of the radiation can include a combination of waves linearly polarized on a first direction, waves linearly polarized on a second direction that is perpendicular to the first direction, and waves linearly polarized on directions that can be decomposed into the first direction and the second direction. The radiation can include one or more other portions, defined by, e.g., wavelength. As used herein, a receiving area of the device refers to an area through which the radiation can pass to strike onto, or be selectively absorbed by, at least one of the features on the substrate of the device. Merely by way of example, the receiving area can comprise an opening. The opening can be of any shape, e.g., a circle, a triangle, a rectangle, a square, a parallelogram, a quadrilateral, a polygon, a slit, or the like. The radiation can be substantially perpendicular to the substrate, or can be at a different angle.

According to an embodiment, the device comprises a substrate, a first feature, and a second feature. At least one of the substrate, the first feature, and the second feature can comprise at least one semiconductor material, e.g., silicon, germanium, boron, tellurium, selenium, tin, a III-V group compound semiconductor, and a II-VI group compound semiconductor, or the like, or a combination thereof. The first feature can extend substantially perpendicularly from the substrate. The second feature can extend substantially perpendicularly from the substrate.

The term “feature” (e.g., a first feature or a second feature) used herein means a structure that has a height in a direction perpendicular to the substrate (hereafter referred to as the “normal direction”), a transverse dimension in a direction parallel to the substrate (hereafter referred to as the “transverse direction”), and a width in a direction perpendicular to both the normal direction and the transverse direction (hereafter referred to as the “thickness direction”). A feature can have a height that is larger than its width or its transverse dimension. Merely by way of example, a feature has a width in the order of 10 nanometers (nm) (e.g., approximately 20 nm, or approximately 40 nm, or approximately 60 nm, or approximately 80 nm, or approximately 100 nm, or larger than 100 nm). As another example, the feature has a width in the order of 100 nm, e.g., approximately 100 nm, 150 nm, 200 nm, 250 nm, 300 nm, 400 nm, 500 nm, or larger than 500 nm. A feature can have a transverse dimension in the order of 10 nm (e.g., approximately 20 nm, or approximately 40 nm, or approximately 60 nm, or approximately 80 nm, or approximately 100 nm, or larger than 100 nm). As another example, the feature has a width in the order of 100 nm, e.g., approximately 100 nm, 150 nm, 200 nm, 250 nm, 300 nm, 400 nm, 500 nm, or larger than 500 nm. A feature can have a height in the order of 100 nm (e.g., approximately 200 nm, or approximately 400 nm, or approximately 600 nm, or approximately 800 nm, or approximately 1 micrometer (micron), or larger than 1 micron), or in the order of 1 micron (e.g., approximately 1 micron, approximately 2 microns, approximately 3 microns, approximately 5 microns, approximately 8 microns, approximately 10 microns, or larger than 10 microns).

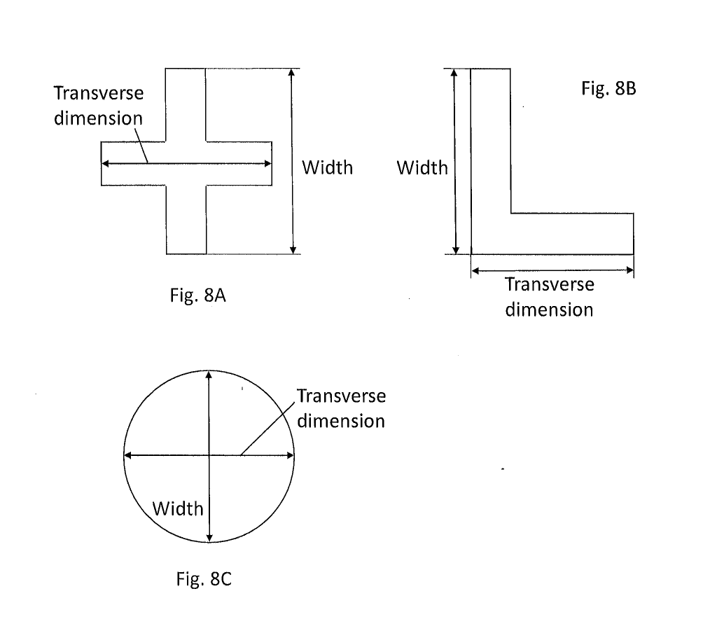

A feature can have any suitable shape in a cross-section parallel to the substrate, such as a rectangle, a square, a circle, a cross, an ellipse, convex-convex (i.e. like a double-convex lens), concave-concave (i.e. like a double-concave lens), plano-convex (i.e. like a plano-convex lens), plano-concave (i.e. like a plano-concave lens). If the shape has a constant width and a constant transverse dimension (except at one or more angles), e.g., a rectangle or a rounded rectangle, a square or a rounded square, the aspect ratio of the feature is the ratio of the transverse dimension (i.e. a dimension in the transverse direction) to the width (i.e. the dimension in the thickness direction). If the shape has a variable dimension along the thickness direction or a variable dimension along the transverse dimension across a cross-section, e.g., the shape being an ellipse, a circle, a cross, convex-convex, concave-concave, plano-convex, plano-concave, the width is the largest dimension in the thickness direction, the transverse dimension is the largest dimension in the transverse direction, and the aspect ratio of the feature is the ratio of the transverse dimension to the width. Merely by way of example, if the cross-section is a circle, the width and the transverse dimension are the same, both equal to the diameter of the circle. As another example, if the cross-section is a cross, the width is the largest dimension in the thickness direction, the transverse dimension is the largest dimension in the transverse direction, and the aspect ratio of the feature is the ratio of the transverse dimension to the width. FIGS. 8A-8C discussed below show exemplary cross-sections of features.

A feature can react to radiation incident on the receiving area of the device, or a portion thereof. Here, the term “react” is meant to broadly encompass absorbing, reflecting, coupling to, detecting, interacting with, converting to a signal (e.g., an electrical signal), etc. A feature can comprise at least one semiconductor material, e.g., silicon, germanium, boron, tellurium, selenium, tin, a III-V group compound semiconductor, and a II-VI group compound semiconductor, or the like, or a combination thereof. As already discussed, the radiation can include one or more portions, defined by, e.g., wavelength. A feature can be operable to selectively absorb a portion of the radiation, wherein the wavelengths of the portion of the radiation are within a range.

As used herein, a feature that “selectively absorbs” a portion of the radiation means that the feature significantly absorbs that portion of radiation without also greatly absorbing another portion of the radiation. Merely by way of example, a feature can be configured to absorb at least 30%, or at least 40%, or at least 50%, or at least 60%, or at least 70%, or at least 80%, or at least 90% of a first portion of the radiation whose wavelengths are within a first range, while absorb no more than 50%, or no more than 40%, or no more than 30%, or no more than 20%, or no more than 10% of a second portion of the radiation whose wavelengths are within a second range, the first range being different from the second range. The first range of wavelengths or the second range of wavelengths can be chosen based on the intended use of the device. Merely by way of example, the range of wavelengths can be from approximately 450 nm to approximately 495 nm, or from approximately 495 nm to approximately 570 nm, or from approximately 570 nm to approximately 590 nm, or from approximately 620 nm to approximately 740 nm. A feature can be configured to selectively absorb another portion of the radiation whose wavelengths are within another range, e.g., ultraviolet radiation, infrared radiation, or the like.

According to an embodiment, the transverse dimension or the width of a feature can be chosen such that the value that the transverse dimension (or the width) times the refractive index of the material of the feature is approximately half the wavelengths of the waves the feature can selectively absorb. The aspect ratio, the ratio of the transverse dimension to the width of a feature, can be close to 1. The aspect ratio can be, e.g., approximately 0.6:1, or approximately 0.8:1, or approximately 1.2:1, or approximately 1.5:1, or approximately 1.8:1, or approximately 2:1. The aspect ratio can be less than 5, or less than 4, or less than 3, or less than 2, or less than 1.5. Merely by way of example, the width and the transverse dimension of a feature are chosen such that the feature can selectively absorb a portion of the radiation that includes a combination of waves whose wavelengths are within a range; the portion of the radiation includes a combination of waves linearly polarized on the transverse direction of the feature, waves linearly polarized along the thickness direction of the feature (that is perpendicular to the transverse direction of the feature), and waves linearly polarized on a direction that can be decomposed into the first direction and the second direction. The width and the transverse dimension of a feature (the largest dimensions along the thickness direction and along the transverse direction of a cross-section of the feature, respectively) can be chosen such that the feature is selective with respect to wavelengths (i.e. it can selectively absorb a portion of the radiation whose wavelengths are within a range), but not selective with respect to linear polarization (i.e. it can selectively absorb waves linearly polarized on a different direction). This can be achieved by, e.g., configuring a feature such that its width and its transverse dimension are similar. For example, the feature can have a cross-section of a circle, a square, a cross, an L shape (see, e.g., FIGS. 8A-8C). According to an embodiment, an individual feature is configured such that it is selective with respect to both wavelengths and linear polarization; a group of two such features positioned perpendicular to each other (i.e. the transverse direction of a feature is perpendicular to the transverse direction of the other feature) can lack the selectivity with respect to linear polarization.

The height of a feature can be at least 2 times, or at least 3 times, or at least 4 times, or at least 5 times, or at least 6 times, or at least 8 times, or at least 10 times, or at least 20 times, or at least 40 times, or at least 50 times of the wavelengths of the portion of the radiation that the feature is operable to absorb. The height of a feature can be at least 2 times, or at least 3 times, or at least 4 times, or at least 5 times, or at least 6 times, or at least 8 times, or at least 10 times, or at least 20 times, or at least 40 times, or at least 50 times of the transverse dimension of the feature. The height of a feature can be at least 2 times, or at least 3 times, or at least 4 times, or at least 5 times, or at least 6 times, or at least 8 times, or at least 10 times, or at least 20 times, or at least 40 times, or at least 50 times of the width of the feature.

According to an embodiment, the first feature and the second feature of the device are configured to react differently to radiation incident on the receiving area of the device. The first feature can be operable to selectively absorb a first portion of the radiation, wherein the wavelengths of the first portion of the radiation are within a first range. The second feature can be operable to selectively absorb the second portion of the radiation, wherein the wavelengths of the second portion of the radiation are within a second range. The first range of wavelengths can be different from the second range of wavelengths. Merely by way of example, the first range of wavelengths or the second range of wavelengths can be from approximately 450 nm to approximately 495 nm, or from approximately 495 nm to approximately 570 nm, or from approximately 570 nm to approximately 590 nm, or from approximately 620 nm to approximately 740 nm. The first range of wavelengths or the second range of wavelengths can fall in the range of ultraviolet or the range of infrared.

The device can include more than one first feature. At least two of the multiple first features can have a same orientation. That is, the transverse directions of at least two of the multiple first features are parallel to each other. As used herein, an orientation of a feature can be defined by its transverse direction or its thickness direction. The multiple first features can be equally spaced from each other. The parallel first features can have a first pitch (i.e. spacing between adjacent parallel first features in the thickness direction thereof) of at least 10 nm, or at least 20 nm, or at least 30 nm, or at least 40 nm, or at least 50 nm, or at least 60 nm, or at least 80 nm, or at least 100 nm, or larger than 100 nm. The first pitch can be smaller than 500 nm, or smaller than 400 nm, or smaller than 300 nm, or smaller than 200 nm, or smaller than 150 nm, or smaller than 120 nm, or smaller than 100 nm, or smaller than 80 nm, or smaller than 60 nm, or smaller than 50 nm. At least two of the multiple first features can have different orientations. Merely by way of example, at least two of the multiple first features are positioned to be substantially perpendicular to each other, i.e. the transverse direction of one first feature being substantially perpendicular to the transverse direction of another first feature. As another example, at least two of the multiple first features are positioned at an angle other than 90°.

The device can include more than one second feature. At least two of the multiple second features can have a same orientation. That is, the transverse directions of at least two of the multiple second features are parallel to each other. The multiple second features can be equally spaced from each other. The parallel second features can have a second pitch (i.e. spacing between adjacent parallel second features in the thickness direction thereof) of at least 10 nm, or at least 20 nm, or at least 30 nm, or at least 40 nm, or at least 50 nm, or at least 60 nm, or at least 80 nm, or at least 100 nm, or larger than 100 nm. The second pitch can be smaller than 500 nm, or smaller than 400 nm, or smaller than 300 nm, or smaller than 200 nm, or smaller than 150 nm, or smaller than 120 nm, or smaller than 100 nm, or smaller than 80 nm, or smaller than 60 nm, or smaller than 50 nm. At least two of the multiple second features can have different orientations. Merely by way of example, at least two of the multiple first features are positioned to be substantially perpendicular to each other, i.e. the transverse direction of one second feature being substantially perpendicular to the transverse direction of another second feature. As another example, at least two of the multiple second features are positioned at an angle other than 90°.

According to an embodiment, at least one first feature and at least one second feature can have different orientations. According to an embodiment, at least one first feature and at least one second feature can have a same orientation. That is, at least one first feature and at least one second feature are parallel to each other or have the same transverse direction.

According to an embodiment, the one or more first features and the one or more second features are positioned on the substrate such that at least a first percentage of the first portion of the radiation incident on the receiving area can be absorbed by the one or more first features, and at least a second percentage of the second portion of the radiation incident on the receiving area can be absorbed by the one or more second features. The first percentage or the second percentage can be at least 30%, or at least 40%, or at least 50%, or at least 60%, or at least 70%, or at least 80%.

According to an embodiment, the device can comprise a third feature. The third feature can extend substantially perpendicularly from the substrate. The third feature can be operable to selectively absorb a third portion of the radiation, wherein the wavelengths of the third portion of the radiation are within a third range. The third range of wavelengths can be different from the first range of wavelengths, or the second range of wavelengths. The third range of wavelengths can be the same as one of the first range or the second range. The third range of wavelengths can be from approximately 450 nm to approximately 495 nm, or from approximately 495 nm to approximately 570 nm, or from approximately 570 nm to approximately 590 nm, or from approximately 620 nm to approximately 740 nm.

The device can include more than one third feature. At least two of the multiple third features can have a same orientation. That is, at least two of the multiple third features are parallel to each other or have the same transverse direction. At least some adjacent third features of the multiple third features having the same orientation can be equally spaced from each other. The parallel third features can have a third pitch (i.e. spacing between adjacent parallel third features in the thickness direction thereof) of at least 10 nm, or at least 20 nm, or at least 30 nm, or at least 40 nm, or at least 50 nm, or at least 60 nm, or at least 80 nm, or at least 100 nm, or larger than 100 nm. The second pitch can be smaller than 500 nm, or smaller than 400 nm, or smaller than 300 nm, or smaller than 200 nm, or smaller than 150 nm, or smaller than 120 nm, or smaller than 100 nm, or smaller than 80 nm, or smaller than 60 nm, or smaller than 50 nm. At least two of the multiple third features can have different orientations. Merely by way of example, at least two of the multiple third features are positioned to be substantially perpendicular to each other. As another example, at least two of the multiple third features are positioned at an angle other than 90°.

According to an embodiment, at least one third feature has a different orientation from at least one first feature or at least one second feature. According to an embodiment, at least one third feature has a same orientation as at least one first feature or at least one second feature. That is, at least one third feature and at least one first feature are parallel to each other or have the same transverse direction, or at least one third feature and at least one second feature are parallel to each other or have the same transverse direction.

According to an embodiment, the one or more first features, the one or more second features, and the one or more third features are positioned on the substrate such that at least a first percentage of the first portion of the radiation incident on the receiving area can be absorbed by the one or more first features, at least a second percentage of the second portion of the radiation incident on the receiving area can be absorbed by the one or more second features, and at least a third percentage of the third portion of the radiation incident on the receiving area can be absorbed by the one or more third features. The first percentage, the second percentage, or the third percentage can be at least 30%, or at least 40%, or at least 50%, or at least 60%, or at least 70%, or at least 80%. At least two of the first percentage, the second percentage, and the third percentage can be the same or different.

A feature can have a surrounding area. A surrounding area refers to an area around the feature, and the feature is operable to selectively absorb at least 30%, or at least 40%, or at least 50%, or at least 60%, or at least 70%, or at least 80%, or at least 90% of a portion of the radiation (defined by, e.g., wavelength) in the surrounding area. The size or shape of the surrounding area can depend on parameters including the dimension of the feature (e.g., width, transverse dimension, and/or height), the material of the feature, the media surrounding the feature, or the like, or a combination thereof. The size of the surrounding area, refers to the largest dimension of a cross-section of the surrounding area parallel to the substrate. The size of the surrounding area of a feature can be in the same order as, or an order higher than the transverse dimension of the feature, or larger. Merely by way of example, if the transverse dimension is in the range of approximately 50 nm to approximately 100 nm, the size of the surrounding area can be in the range of approximately 100 nm to approximately 1 micron.

A first feature can have a first surrounding area, and can selectively absorb at least 30%, or at least 40%, or at least 50%, or at least 60%, or at least 70%, or at least 80%, or at least 90% of a first portion of the radiation (whose wavelengths are within a first range) in the first surrounding area. A second feature can have a second surrounding area, and can selectively absorb at least 30%, or at least 40%, or at least 50%, or at least 60%, or at least 70%, or at least 80%, or at least 90% of a second portion of the radiation (whose wavelengths are within a second range) in the second surrounding area. According to an embodiment, the first feature and the second feature are positioned on the substrate such that the first surrounding area and the second surrounding area overlap by at least 30%, or at least 40%, or at least 50%, or at least 60%, or at least 70%, or at least 80%, or at least 90% of the smaller of the first surrounding area and the second surrounding area.

The device can comprise a third feature having a third surrounding area. The third feature can selectively absorb at least 30%, or at least 40%, or at least 50%, or at least 60%, or at least 70%, or at least 80%, or at least 90% of a third portion of the radiation (whose wavelengths are within a third range) in the third surrounding area. According to an embodiment, the first feature and the third feature are positioned on the substrate such that the first surrounding area and the third surrounding area overlap by at least 30%, or at least 40%, or at least 50%, or at least 60%, or at least 70%, or at least 80%, or at least 90% of the smaller of the first surrounding area and the third surrounding area. According to an embodiment, the first feature, the second feature, and the third feature are positioned on the substrate such that the first surrounding area, the second surrounding area, and the third surrounding area overlap by at least 30%, or at least 40%, or at least 50%, or at least 60%, or at least 70%, or at least 80%, or at least 90% of the smallest of the first surrounding area, the second surrounding area, and the third surrounding area.

A feature, e.g., the first feature or the second feature, can selectively absorb a portion of the radiation, e.g., a first portion of the radiation or a second portion of the radiation, and at least a part of the absorbed radiation can generate charge carriers (e.g., holes and electrons) in the feature. The feature can be configured such that the opposite charge carriers can move toward different regions of the feature. Merely by way of example, the feature can form a p-i-n junction, a p-n junction, alone or with the substrate, or the feature can include intrinsic semiconductor. The feature can be configured to convert at least some of absorbed radiation to charge carriers, and the charge carriers of opposite charges can move in specific directions to different regions in the feature depending on the specific configuration of the feature.

According to an embodiment, the device includes a charge carrier collector. As used herein, a charge carrier collector can collect charge carriers reaching the charge carrier collector, and allow for the charge carriers collected thereon to be detected or measured in a detection/measurement circuitry. Merely by way of example, a charge carrier collector can be disposed on a feature to collect the charge carriers reaching that charge carrier collector. As another example, a charge carrier collector can be positioned at the interface between a feature and the substrate, or within the substrate, or on a surface of the substrate (e.g., a top surface, a sidewall, or a bottom surface), to collect the charge carriers reaching that charge carrier collector. The charge carriers can stay/accumulate on the charge carrier collector when the detection/measurement circuitry is open, and can be detected/measured when the detection/measurement circuitry is closed. This configuration can allow the temporal separation of the generation of the charge carriers and their detection/measurement.

Merely by way of example, the device comprising two features, a first feature and a second feature, and two charge carrier collectors, a first charge carrier collector and a second charge carrier collector. The device is configured such that when it is exposed to radiation, at least a part of the radiation is absorbed by the first feature or the second feature of the device. The charge carriers of one type (e.g., holes, or electrons) generated by or in the first feature can move to and accumulate on the first charge carrier collector, and remain there. The charge carriers of one type (e.g., holes, or electrons) generated by or in the second feature can move to and accumulate on the second charge carrier collector, and remain there. The charge carriers on the first charge carrier collector can be detected/measured after the device is connected to, e.g., a meter or reader, such that a closed detection/measurement circuitry forms with the first charge carrier collector and an electrical field is applied. Likewise, the charge carriers on the second charge carrier collector can be detected/measured after the device is connected to, e.g., a meter or reader, such that a closed detection/measurement circuitry forms with the second charge carrier collector and an electrical field is applied.

As another example, the device can further comprise a first corresponding charge carrier collector to form a pair of charge carrier collectors with the first charge carrier collector; or the device can further comprise a second corresponding charge carrier collector to form a pair of charge carrier collectors with the second charge carrier collector. The charge carriers of the opposite charges (e.g., holes, or electrons) generated by or in the first feature can move to and accumulate on one of the first charge carrier collector and the first corresponding charge carrier collector, respectively. The first corresponding charge carrier collector and the first charge carrier collector can both be part of the detection/measurement circuitry for detecting/measuring the charge carriers generated by or in the first feature. Likewise, the charge carriers of the opposite charges (e.g., holes, or electrons) generated by or in the second feature can move to and accumulate on one of the second charge carrier collector and the second corresponding charge carrier collector, respectively. The second corresponding charge carrier collector and the second charge carrier collector can both be part of the detection/measurement circuitry for detecting/measuring the charge carriers generated by or in the first feature.

If a detection/measurement circuitry is closed when the device is exposed to radiation, the charge carriers generated by or in the first feature or the second feature can move to the charge carrier collectors and be detected/measured simultaneously. The device can be configured such that there is little or no dark current (no current when the device is not exposed to radiation, at least some of which can be absorb by the features of the device) when an electrical field is applied.

In the following detailed description, reference is made to the accompanying drawings, which form a part thereof. In the drawings, similar symbols typically identify similar components, unless the context dictates otherwise. The drawings are not to scale.

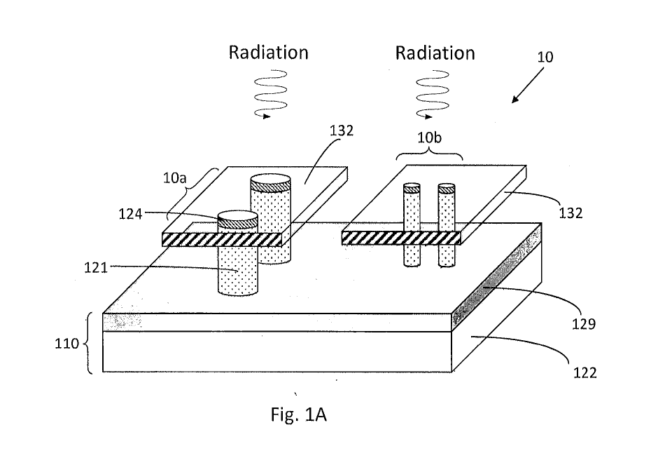

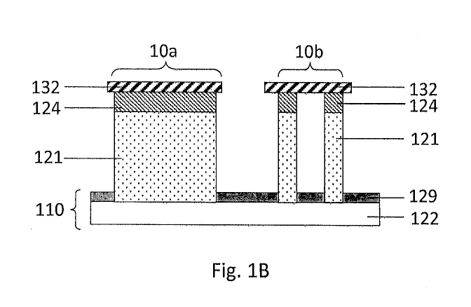

FIGS. 1A and 1B show a perspective view and a cross-sectional view of a device 10 according to one embodiment. Multiple first features 10a and multiple second features 10b of a substrate 110 are illustrated. The device 10, however, can comprise more or fewer first features, or more or fewer second features; the device can comprise one or more third or other features that can selectively absorb a third or another portion of the radiation incident on the receiving area of the device. The first features 10a and the second features 10b extend substantially perpendicular from the substrate 110, but in different transverse directions. The first features 10a are substantially parallel to each other. The second features 10b are substantially parallel to each other. However, the first features 10a or the second features 10b can be positioned on the substrate 110 at different orientations from those illustrated in FIG. 1A.

As illustrated, the first features 10a and the second features 10b have similar compositions. A first features 10a and the second features 10b can form a p-i-n junction with the substrate 110, the p-i-n junction being functional to convert at least some of the radiation impinged thereon to an electrical signal. A first feature 10a or a second feature 10b can comprise a heavily doped semiconductor layer 124 disposed on a lightly doped semiconductor layer or intrinsic semiconductor layer 121. The substrate 110 can comprise another lightly doped semiconductor layer 122 of the opposite type from the heavily doped semiconductor layer 124. The heavily doped semiconductor layer 124 can be a p-type or an n-type. The lightly doped semiconductor layer or intrinsic semiconductor layer 121 of the feature 10a or 10b can be disposed on the lightly doped semiconductor layer 122. The layers 121, 122 and 124 form the p-i-n junction. It is understood that at least one of the first features 10a can form a p-n junction, alone or with the substrate, or can include an intrinsic semiconductor or a metal semiconductor junction. It is understood that at least one of the second features 10b can form a p-n junction, alone or with the substrate, or can include an intrinsic semiconductor or a metal semiconductor junction.

The first features 10a and the second features 10b are functional to react differently to radiation incident on the receiving area of the device. A first feature 10a has a first width and a first transverse dimension. The first features 10a can be configured to selectively absorb a first portion of the radiation impinged on the receiving area of the device, wherein the wavelengths of the first portion of the radiation are within a first range. A second feature 10b has a second width and a second transverse dimension. The second features 10b are configured to selectively absorb a second portion of the radiation impinged on the receiving area of the device, wherein the wavelengths of the second portion of the radiation are within a second range. The aspect ratio of each of the first features 10a or the second features 10b can be, e.g., approximately 0.6, approximately 0.8, approximately 1, approximately 1.2, approximately 1.5:1. The first width or the second width can be less than 200 nm, or less than 150 nm, or approximately 100 nm, or approximately 80 nm, or approximately 60 nm, or approximately 50 nm, or 40 nm or less. The first transverse dimension or the second transverse dimension can be less than 200 nm, or less than 150 nm, or approximately 150 nm, or approximately 120 nm, or approximately 100 nm, or approximately 80 nm, or approximately 60 nm, or approximately 50 nm, or approximately 40 nm. The heights of the first features 10a or those of the second features 10b can be the same or different. The first features or the second features can comprise at least one semiconductor material, e.g., silicon, germanium, boron, tellurium, selenium, tin, a III-V group compound semiconductor, and a II-VI group compound semiconductor, or the like, or a combination thereof. The first range of wavelengths or the second range of wavelengths can be, for example, from approximately 450 nm to approximately 495 nm, or from approximately 495 nm to approximately 570 nm, or from approximately 570 nm to approximately 590 nm, or from approximately 620 nm to approximately 740 nm. The first range and the second range can be different.

Space between the first features 10a and the second features 10b can be filled with or comprise a transparent material. The transparent material can constitute a cladding layer. The cladding layer can enclose at least a part of one of the first features or at least a part of one of the second features. The cladding layer can comprise at least one material selected from the group consisting of plasma enhanced Si₃N₄, plasma enhanced SiO₂, and SiO₂, or the like, or a combination thereof. The transparent material, e.g., the cladding layer, can also provide mechanical support for the first features 10a, or the second features 10b. The cladding layer can be configured to provide a graded refractive index such that a refractive index of the enclosed first feature is higher than that of the cladding layer, or a refractive index of the enclosed second feature is higher than that of the cladding layer.

The device 10 can further comprise electrical components configured to detect an electrical signal from the first features 10a or the second features 10b. Merely by way of example, a transparent electrode 132 is disposed or supported on at least some of the first features 10a, or a transparent electrode 132 disposed or supported on at least some of the second features 10b. The transparent electrode 132 can serve as a charge carrier collector that can collect charge carriers reaching the electrode 132. The transparent electrode 132 can comprise a transparent conductive oxide (TCO). The transparent electrode 132 can allow at least a part of the radiation to pass through and strike the first features 10a and/or the second features 10b. The TCO can comprise one or more suitable materials such as indium tin oxide, aluminum zinc oxide, zinc oxide, zinc indium oxide and graphene. The transparent electrode 132 on the first features 10a can be separate or otherwise substantially electrically insulated from the transparent electrode 132 on the second features 10b. The transparent electrode 132 on one first feature 10a can be separate or otherwise substantially electrically insulated from the transparent electrode 132 on another first feature 10a. The transparent electrode 132 on one second feature 10b can be separate or otherwise substantially electrically insulated from the transparent electrode 132 on another second feature 10b.

Although charge carrier collectors formed by the transparent electrodes 132 are visible and denoted in FIGS. 1A and 1B, the device 10 illustrated therein can include another charge carrier collector as discussed elsewhere in the disclosure. Merely by way of example, the device 10 can comprise a charge carrier collector at the interface of the first features 10a (or the second features 10b) and the substrate 110, or within the substrate 110, or at a surface (e.g., the bottom surface) of the substrate 110.

A reflective material or layer 129 can be deposited on at least a part of the area of the substrate 110 between the first features 10a and between the second features 10b. Sidewalls of the features 10a or 10b can be free of the reflective layer 129. Exemplary material suitable for use in the reflective layer 129 includes aluminum, gold, chromium, silver, copper, titanium, nickel, a heavily doped semiconductor, or the like, or an alloy thereof, or a combination thereof. The substrate 110 can have a height in the normal direction (the same as the normal direction of a first feature 10a or that of a second feature 10b) of approximately 1 to 700 microns. The substrate 110 can comprise one or more layers other than the lightly doped semiconductor layer 122 and the reflective material or layer 129.

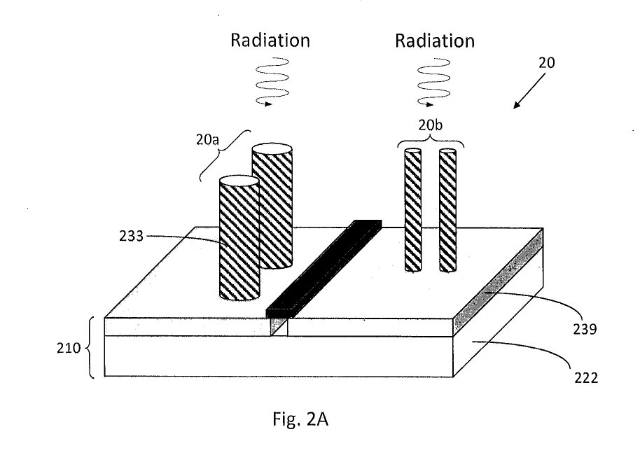

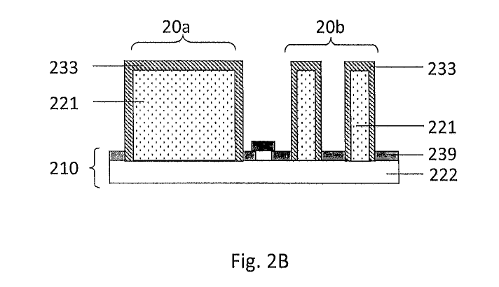

FIGS. 2A and 2B show a perspective view and a cross-sectional view of a device 20 according to one embodiment. Multiple first features 20a and multiple second features 20b of a substrate 210 are illustrated. The device 20, however, can comprise more or fewer first features, or more or fewer second features; the device can comprise one or more third or other features that can selectively absorb a third or another portion of the radiation incident on the receiving area of the device. The arrangement of the first features 20a and the second features 20b, including the orientations, the relative locations, can be different from that shown in FIGS. 2A and 2B. The first features 20a and the second features 20b can be similar to the first features 10a and the second features 10b described in connection with FIGS. 1A-1C except for the configuration of the p-i-n junction, the p-i-n junction being functional to convert at least some of radiation impinged thereon to an electrical signal. A first features 20a or a second feature 20b can comprise a core 221 of lightly doped semiconductor or intrinsic semiconductor, and a shell 233 of a heavily doped semiconductor, the shell 233 being conformally disposed over the core 221. The substrate 210 can comprise a lightly doped semiconductor layer 222 of the opposite type from the shell 233. The shell 233 can be a p-type or an n-type. The core 221 can be disposed on the lightly doped semiconductor layer 222. The shell 233, the core 221 and the layer 222 can form the p-i-n junction. It is understood that at least one of the first features 20a can form a p-n junction, alone or with the substrate, or can include an intrinsic semiconductor or a metal semiconductor junction. It is understood that at least one of the second features 20b can form a p-n junction, alone or with the substrate, or can include an intrinsic semiconductor or a metal semiconductor junction.

A metal layer 239 can be supported on and electrically connected to portions of the heavily doped layer 233 by way of, e.g., forming an Ohmic contact. The metal layer 239 that is electrically connected to the first features 20a can be separate or otherwise substantially electrically insulated from the metal layer 239 that is electrically connected to the second features 20b. The metal layer 239 that is supported on one first feature 20a can be separate or otherwise substantially electrically insulated from the metal layer 239 that is supported on another first feature 20a. The metal layer 239 that is supported on one second feature 20b can be separate or otherwise substantially electrically insulated from the metal layer 239 that is supported on another second feature 20b. The metal layer 239 can also function as a reflective layer.

Although charge carrier collectors formed by the metal layer 239 are visible and denoted in FIGS. 2A and 2B, the device 20 illustrated therein can include another charge carrier collector as discussed elsewhere in the disclosure. Merely by way of example, the device 20 can comprise a charge carrier collector at the interface of the first features 20a (or the second features 20b) and the substrate 210, or within the substrate 210, or at a surface (e.g., the bottom surface) of the substrate 210.

A reflective material or layer can be deposited on at least a part of the area of the substrate 210 between the first features 20a and between the second features 20b. Space between the first features 20a and the second features 20b can be filled with or comprise a transparent material. The transparent material can constitute a cladding layer, similar to the cladding layer described in connection with FIGS. 1A and 1B. The device 20 can further comprise electrical components configured to detect the electrical signals from the first features 20a or the second features 20b. The substrate 210 can have a height in the normal direction (the same as the normal direction of a first feature 20a or that of a second feature 20b) of approximately 1 to 700 microns. The substrate 210 can comprise one or more layers other than the lightly doped semiconductor layer 222 and the metal layer 239.

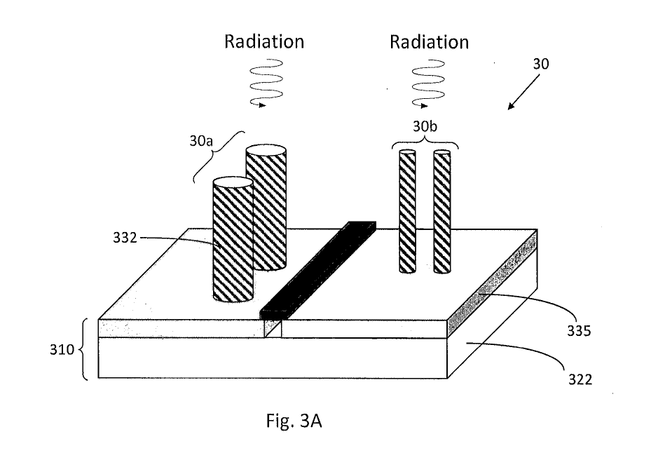

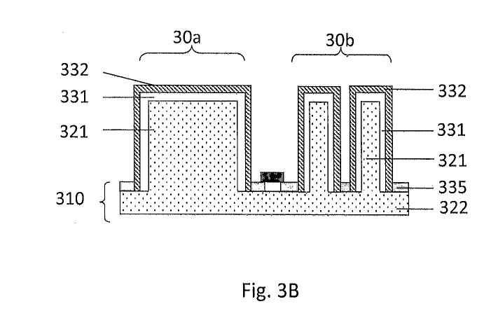

FIGS. 3A and 3B show a perspective view and a cross-sectional view of a device 30 according to one embodiment. Multiple first features 30a and multiple second features 30b of a substrate 310 are illustrated. The device 30, however, can comprise more or fewer first features, or more or fewer second features; the device can comprise one or more third or other features that can selectively absorb a third or another portion of the radiation incident on the receiving area of the device. The arrangement of the first features 30a and the second features 30b, including the orientations, the relative locations, can be different from that shown in FIGS. 3A and 3B. The first features 30a and the second features 30b can be similar to the first features 10a and the second features 10b described in connection with FIGS. 1A-1C except for the configuration of the p-i-n junction, the p-i-n junction being functional to convert at least some of radiation impinged thereon to an electrical signal. A first feature 30a or a second feature 30b can comprise a core 321 of lightly doped semiconductor, an intermediate shell 331 of an intrinsic semiconductor, and an outer shell 332 of a doped semiconductor. The intermediate shell 331 can be conformally disposed over the core 321. The outer shell 332 can be conformally disposed over the intermediate shell 331. The outer shell 332 is of the opposite type from the core 321. The outer shell 332 can be a p-type or an n-type. The outer shell 332, the intermediate shell 331, and the core 321 form the p-i-n junction. The substrate can comprise a layer 322. The layer 322 can comprise a lightly doped semiconductor layer of the opposite type from the heavily doped outer shell 332. Alternatively, the layer 322 can comprise an intrinsic semiconductor.

The substrate 310 can further comprise a metal layer 335. The metal layer 335 is disposed on the features 30a and 30b in such a way that the sidewalls of the features 30a and 30b can be free of the metal layer 335. The metal layers 335 can form, e.g., an Ohmic contact with portions of the layer 332. Exemplary metal suitable for use in the metal layer 335 includes aluminum, gold, chromium, silver, copper, titanium, nickel, a heavily doped semiconductor, or the like, or an alloy thereof, or a combination thereof. The metal layer 335 that is supported on or electrically connected with the first features 30a can be separate or otherwise electrically insulated from the metal layer 335 that is electrically connected to the second features 30b. The metal layer 335 that is supported on or electrically connected to one first feature 30a can be separate or otherwise electrically insulated from the metal layer 335 that is electrically connected to another first feature 30a. The metal layer 335 that is electrically connected to one second feature 30b can be separate or otherwise substantially electrically insulated from the metal layer 335 that is electrically connected to another second feature 30b. The metal layer 335 can also function as a reflective layer.

Although charge carrier collectors formed by the metal layers 335 are visible and denoted in FIGS. 3A and 3B, the device 30 illustrated therein can include another charge carrier collector as discussed elsewhere in the disclosure. Merely by way of example, the device 30 can comprise a charge carrier collector at the interface of the first features 30a (or the second features 30b) and the substrate 310, or within the substrate 310, or at a surface (e.g., the bottom surface) of the substrate 310.

Space between the first features 30a and the second features 30b can be filled with or comprise a transparent material. The transparent material can constitute a cladding layer, similar to the cladding layer described in connection with FIGS. 1A and 1B. The device 30 can further comprise electrical components configured to detect the electrical signals from the first features 30a or the second features 30b. A reflective material can be deposited on at least a part of the area of the substrate 310 between the first features 30a and between the second features 30b. The substrate 310 can have a height in the normal direction of approximately 1 to 700 microns. The substrate 310 can comprise one or more layers other than the layer 322 and the metal layer 335.

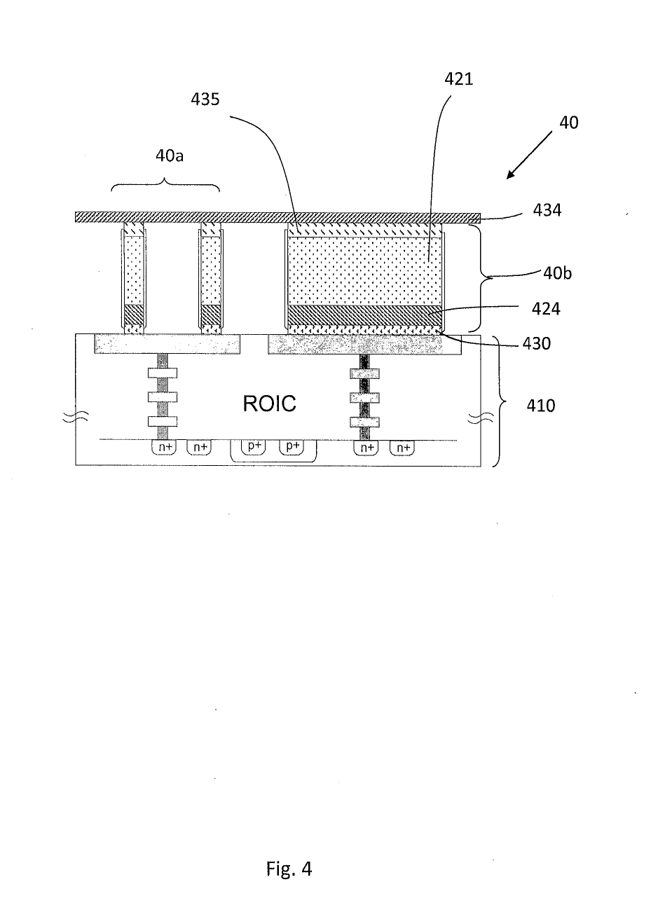

FIG. 4 shows a device 40 according to one embodiment. Multiple first features 40a and multiple second features 40b of a substrate 410 are illustrated. The device 40, however, can comprise more or fewer first features, or more or fewer second features; the device can comprise one or more third or other features that can selectively absorb a third or another portion of the radiation incident on the receiving area of the device. The arrangement of the first features 40a and the second features 40b, including the orientations, the relative locations, can be different from that shown in FIGS. 4A and 4B. The first features 40a and the second features 40b can be similar to the first features 10a and the second features 10b described in connection with FIGS. 1A-1C except for the formation of the p-i-n junction, the p-i-n junction being functional to convert at least some of radiation impinged thereon to an electrical signal. As illustrated, the p-i-n junction is formed along the normal direction of a first feature 40a or of the second feature 40b. A first feature 40a or a second feature 40b can comprise a first heavily doped semiconductor layer 435, a lightly doped semiconductor layer or intrinsic semiconductor layer 421, and a second heavily doped layer 424. The first heavily doped semiconductor layer 435 can be disposed on the lightly doped semiconductor layer or intrinsic semiconductor layer 421. The lightly doped semiconductor layer or intrinsic semiconductor layer 421 can be disposed on the second heavily doped layer 424. The first heavily doped layer 435 can be of the opposite type from the second heavily doped layer 424. The first heavily doped semiconductor layer 435 can be a p type or an n-type. The first heavily doped layer 435, the lightly doped semiconductor layer or intrinsic semiconductor layer 421, and the second heavily doped layer 424 can form the p-i-n junction. A silicide layer 430 is formed from the heavily doped layer 424.

A transparent conductive oxide (TCO) layer 434 can form a transparent electrode, and can comprise one or more suitable materials such as indium tin oxide, aluminum zinc oxide, zinc oxide, zinc indium oxide and graphene. The transparent electrode 434 can be disposed or supported on at least some of the first features 40a, or a transparent electrode 434 can be disposed or supported on at least some of the second features 40b. According to an embodiment, the transparent electrode 434 can beat least some first features 40a or. The transparent electrode 434 can serve as a charge carrier collector. The first features 40a and the second features 40b can be bonded to the substrate 410. The device 40 can further comprise electrical components configured to detect the electrical signals from the first features 40a or the second features 40b, for example, Readout Integrated Circuits (ROIC) in the substrate 410. The ROIC can be connected to the second heavily doped layer 424, and can collect, detect, and/or measure the charge carriers reaching there. As illustrated, the transparent electrode 434 is continuous, and the first features 40a and the second features 40b share the same transparent electrode 434. The electrical signal from the first features 40a and that from the second features can be separated by using separate charge carrier collectors associated with (i.e. operable to collect charge carriers from) the second heavily doped layers 424 (through the silicide layer 430 as illustrated in FIG. 4) of the first features 40a and of the second features 40b.

Space between the first features 40a and the second features 40b can be filled with or comprise a transparent material. The transparent material can constitute a cladding layer, similar to the cladding layer described in connection with FIGS. 1A and 1B. The substrate 410 can have a height in the normal direction (the same as the normal direction of a first feature 40a or that of a second feature 40b) of approximately 1 to 700 microns. The substrate 410 can comprise one or more layers other than those illustrated in FIG. 4.

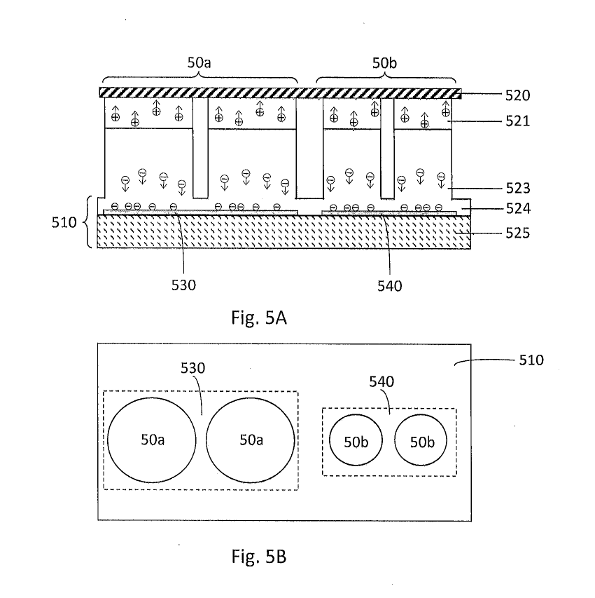

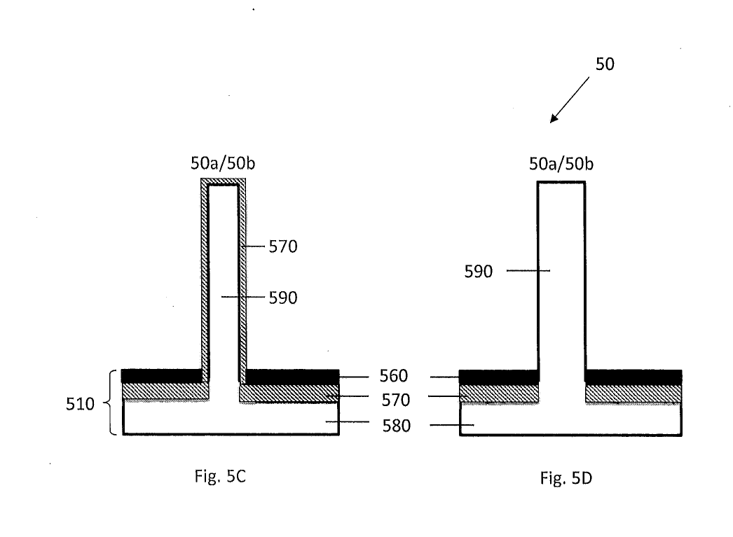

FIGS. 5A-5B show a cross-sectional view and a top view of a device 50 according to one embodiment. Multiple first features 50a and multiple second features 50b of a substrate 510 are illustrated. The device 50, however, can comprise more or fewer first features, or more or fewer second features; the device can comprise one or more third or other features that can selectively absorb a third or another portion of the radiation incident on the receiving area of the device. The arrangement of the first features 50a and the second features 50b, including the orientations, the relative locations, can be different from that shown in FIGS. 5A and 5B. The first features 50a and the second features 50b can be similar to the first features 10a and the second features 10b described in connection with FIGS. 1A-1C, and elsewhere in the disclosure.

FIGS. 5A-5B show a cross-sectional view and a top view of a device 50 according to one embodiment. Multiple first features 50a and multiple second features 50b of a substrate 510 are illustrated. The device 50, however, can comprise more or fewer first features, or more or fewer second features; the device can comprise one or more third or other features that can selectively absorb a third or another portion of the radiation incident on the receiving area of the device. The arrangement of the first features 50a and the second features 50b, including the orientations, the relative locations, can be different from that shown in FIGS. 5A and 5B. The first features 50a and the second features 50b can be similar to the first features 10a and the second features 10b described in connection with FIGS. 1A-1C, and elsewhere in the disclosure.

As illustrated in FIG. 5A, a first feature 50a can comprise a heavily doped semiconductor layer 521, and a lightly doped semiconductor layer 523. The heavily doped semiconductor layer 521 can be a p type or an n-type. The lightly doped semiconductor layer 523 can be of the opposite type from the heavily doped semiconductor layer 521. The heavily doped semiconductor layer 521 can be disposed on the lightly doped semiconductor layer 523. The layers 521 and 523 can form a p-n junction. The substrate 510 can comprise an intrinsic semiconductor layer 524. The lightly doped semiconductor layer 523 can be disposed on the intrinsic semiconductor layer 524. The layers 523 and 524 can form a monocrystal. The first features 50a can be operable to selectively absorb a first portion of the radiation impinged on the receiving area of the device, wherein the wavelengths of the first portion of the radiation are within a first range. The second features 50b can have similar compositions as the first features 50a. The second features can be operable to selectively absorb a second portion of the radiation impinged on the receiving area of the device, wherein the wavelengths of the second portion of the radiation are within a second range. The heights of the first features 50a or those of the second features 50b can be the same or different.

At the bottom of the intrinsic semiconductor layer 524, there can be charge carrier collectors 530 and 540. The charge carrier collector 530 can be located substantially underneath the first features 50a. As used herein, the terms “bottom” or “underneath” indicate the position of a first structural component relative to that of a second structural component in the device. The device can rotate, e.g., in use, so that the first structural component and the second structural component can be, e.g., side by side, while the position of the first structural component relative to that of the second structural component can remain the same. At least one of the charge carrier collectors 530 and 540 can be located inside the intrinsic semiconductor layer 524. The charge carriers generated in the first features 50a can move to the charge carrier collector 530. The movement of the charge carriers can be by way of diffusion, drift (when an electric field is applied), or a combination thereof. The movement or migration can be substantially along the direction from the lightly doped semiconductor layers 523 of the first features 50a to the charge carrier collector 530. The distance between the lightly doped semiconductor layers 523 of the first features 50a and the charge carrier collector 530, referred to as a first distance, can be small such that at least 40%, or at least 50%, or at least 60%, or at least 70%, or at least 80%, or at least 90% of the charge carriers generated in the first features 50a can reach and be collected by the charge carrier collector 530. The charge carrier collector 540 can be located underneath the second features 50b. The charge carriers generated in the second features 50b can move to the charge carrier collector 540 substantially along the direction from the lightly doped semiconductor layers 523 of the second features 50b to the charge carrier collector 540. The distance between the lightly doped semiconductor layers 523 of the second features 50b and the charge carrier collector 540, referred to as a second distance, can be small such that at least 40%, or at least 50%, or at least 60%, or at least 70%, or at least 80%, or at least 90% of the charge carriers generated in the second features 50b can reach and be collected by the charge carrier collector 540. The first distance or the second distance can be smaller than approximately 700 microns, or smaller than approximately 600 microns, or smaller than approximately 500 microns, or smaller than approximately 400 microns, or smaller than approximately 300 microns, or small than approximately 200 microns, or smaller than approximately 100 microns, or smaller than approximately 50 microns, or smaller than approximately 20 microns, or smaller than approximately 10 microns, or smaller than approximately 5 microns, or approximately 1 micron. The first distance and the second distance can be the same or different.

The charge carrier collector 530 and the charge carrier collector 540 are separate or otherwise substantially electrically insulated from each other. Merely by way of example, the space between the charge carrier collectors 530 and 540 can be filled with or comprise the intrinsic semiconductor 524. Few, if any, charge carriers generated in the first features 50a reach or are collected by the charge carrier collector 540. Few, if any, charge carriers generated in the second features 50b reach or are collected by the charge carrier collector 530. This configuration can allow the detection/measurement of the charge carriers generated in the first features 50a substantially independent from the detection/measurement of the charge carriers generated in the second features 50b. The charge carrier collectors 530 and 540 can be substantially electrically insulated from the ambient by, e.g., treating a surface of the charge carrier collector 530 or 540 that is otherwise exposed to the ambient. The insulation can be achieved by coating or covering the otherwise exposed surface with a layer of an electrically insulating material. As illustrated in FIG. 5A, the substrate 510 can comprise an electrically insulating layer 525 that covers the otherwise exposed surfaces of the charge carrier collectors 530 and 540. The electrically insulating layer 525 can, but does not need to form a monocrystal with the intrinsic semiconductor layer 524. The layer 525 can also provide physical support for the device 50. The layer 525 can be a thin coating that does not provide much physical support for the device 50. Although not shown in FIG. 5A, the charge carrier 530 or the charge carrier collector 540 can be connected to a detection/measurement circuitry via, e.g., a conductive wire, or the like.

A charge carrier collector, e.g., the charge carrier collector 530 or the charge carrier collector 540, can comprise a conductive material. The charge carrier collector can comprise metal, e.g., aluminum, gold, chromium, silver, copper, titanium, nickel, a heavily doped semiconductor, or the like, or an alloy thereof, or a combination thereof. The charge carrier collector can comprise a heavily doped semiconductor.

The size of a charge carrier collector, e.g., the charge carrier collector 530 or 540, can be substantially the same as, slightly smaller, or slightly larger than the cross-section of the feature (or the sum of the cross-sections of the features positioned next to each other) from which the charge carrier collector is configured to collect charge carriers. The charge carrier collector 530 can be substantially parallel to the cross-section of the first feature 50a, or the substrate 510. As illustrated in FIG. 5B, two first features 50a are positioned next to each other on the substrate 510, and they can share a charge carrier collector 530 shown in phantom. The size of the charge carrier 530 is slightly larger than the sum of the cross-sections of the two first features 50a. The two second features 50b are positioned next to each other on the substrate 510, and they can share a charge carrier collector 540 shown in phantom. The size of the charge carrier 540 is slightly larger than the sum of the cross-sections of the two second features 50b. The charge carrier collector 540 can be substantially parallel to the cross-section of the second feature 50b, or the substrate 510.

The device 50 can comprise a corresponding charge carrier collector 520 that can collect the charge carriers of the opposite charge from those collected by the charge carrier collector 530 and from those collected by the charge carrier collector 540. It is understood that the detection/measurement of the charge carriers accumulated on the charge carrier collector 530 or 540 can be performed when an electrical field is applied or the detection/measurement circuitry is closed. A corresponding charge carrier collector, e.g., the corresponding charge carrier collector 520, can be an optional way to form a closed detection/measurement circuitry. The corresponding charge carrier collector 520 is not shown in FIG. 5B. The charge carrier collector 520 can be conformally disposed on a first feature 50a or a second feature 50b.

According to the embodiment illustrated in FIG. 5A, the first features 50a and the second features 50b can share the same charge carrier collector 520. Because the charge carrier collector 530 is separate or otherwise substantially electrically insulated from the charge carrier collector 540, the configuration of the charge carrier collector 520 illustrated in FIG. 5A does not compromise the capacity of the device to independently detecting/measuring the charge carriers generated in the first features 50a and the charge carriers generated in the second features 50b. To detect/measure the charge carriers generated in the first features 50a, the corresponding charge carrier collector 520 and the charge carrier collector 530 are connected to a detection/measurement circuitry. To detect/measure the charge carriers generated in the second features 50b, the corresponding charge carrier collector 520 and the charge carrier collector 540 are connected to a detection/measurement circuitry. The charge carrier collector 520 can be a substantially continuously conductive layer. As used herein, a continuously conductive layer indicates that a charge carrier can move from one point to anther of the charge carrier collector while remaining within the charge carrier collector. According to an embodiment, the charge carrier collector 520 electrically connected to the first features 50a can be separate or otherwise electrically insulated from the charge carrier collector 520 electrically connected to the second features 50b, similar to the transparent electrodes 132 illustrated in FIGS. 1A and 1B.

The configuration of the charge carrier collectors 530 and 540 illustrated in FIGS. 5A and 5B is also applicable to a device including a conformal p-i-n junction, similar to the device 20 illustrated in FIGS. 2A and 2B, and the device 30 illustrated in FIGS. 3A and 3B. The device can further can comprise a corresponding charge carrier collector, e.g., one similar to the metal layers 239 illustrated in FIGS. 2A and 2B, or one similar to the metal layers 335 illustrated in FIGS. 3A and 3B. The corresponding charge carrier collector that can be operable to collect charge carriers from the first features 50a can be separate or otherwise substantially electrically insulated from the charge carrier collector that is operable to collect charge carriers from the second features 50b.

According to an embodiment, if the corresponding charge carrier collector associated with the first features 50a is separate or otherwise substantially electrically insulated from the charge carrier collector associated with the second features 50b (e.g., the transparent electrodes 132 illustrated in FIG. 1A, the metal layers 239 illustrated in FIGS. 2A and 2B, and the metal layer 335 illustrated in FIGS. 3A and 3B), the charge carrier collectors 530 and 540 can form a (physically or electrically) continuous layer, without compromising the capacity of the device to independently detecting/measuring the charge carriers generated in the first features 50a and the charge carriers generated in the second features 50b.

FIG. 5C and FIG. 5D show alternative embodiments of the device 50. The device 50 can comprise a drift field to propel the charge carriers towards the charge carrier collector 560 of collection circuits at the front end of the sensor. This is accomplished by surface doping the feature (e.g., 50a/50b, only one feature shown in FIG. 5C and in FIG. 5D), or the area between features, or both. As illustrated, a feature can comprise an intrinsic semiconductor 590. The substrate 510 can comprise a metal layer 560, a doped layer 570, and an intrinsic semiconductor 580. The metal layer 560 can be electrically connected to the doped layer 570 by way of, e.g., forming an Ohmic contact. A feature (e.g., 50a/50b) can comprise the intrinsic semiconductor 590, and the doped layer 570 conformally disposed on the intrinsic semiconductor 590, as illustrated in FIG. 5C. The doped layer 570 can be p-type or n-type, opposite from doped layer 570. In the embodiment illustrated in FIG. 5D, the feature (e.g., 50a/50b) can comprise the intrinsic semiconductor 590, but not a doped layer.

The device 50 can be configured such that there is little or no dark current (no current when the device is not exposed to radiation, at least some of which can be absorb by the features of the device) when an electrical field is applied to form a drift field.

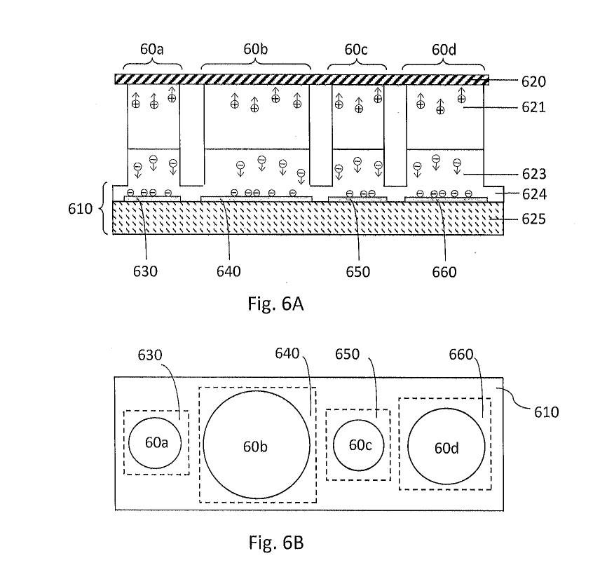

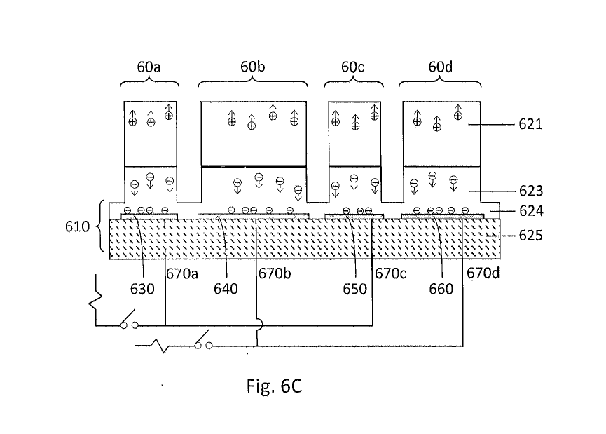

FIGS. 6A-6C show a device 60 according to one embodiment. FIG. 6A is the cross-sectional view of the device 60, and FIG. 6B shows the top view of the device 60. FIG. 6C illustrates an exemplary electrical connection of some of the charge carrier collectors. The device can comprise features 60a, 60b, 60c, and 60d of a substrate 610 as illustrated. Each feature can be operable to selectively absorb a portion of the radiation incident on the receiving area of the device. Merely by way of example, the features 60a and 60c are operable to selectively absorb a first portion of the radiation incident on the receiving area of the device, while the features 60b and 60d are operable to selectively absorb a second portion of the radiation incident on the receiving area of the device. As another example, the features 60a, 60b, 60c, and 60d are operable to selectively absorb different portions of the radiation incident on the receiving area of the device. The first feature 60a can be operable to selectively absorb a first portion of the radiation incident on the receiving area of the device, the second feature 60b can be operable to selectively absorb a second portion, the third feature 60c can be operable to selectively absorb a third portion, and the fourth feature 60d can be operable to selectively absorb a fourth portion. The first portion through the fourth portion of the radiation incident on the receiving area of the device can be defined by, e.g., their wavelengths as described elsewhere in the disclosure. Merely by way of example, each of the first portion through the fourth portion of the radiation incident on the receiving area of the device can have a different range of wavelengths from at least one of the others. The device 60 can comprise more or fewer of any one of the features 60a, 60b, 60c and 60d; the device can comprise one or more other features that can selectively absorb another portion of the radiation incident on the receiving area of the device. The arrangement of the first feature 60a, the second feature 60b, the third feature 60c, and the fourth feature 60d, including the orientations, the relative locations, can be different from that shown in FIGS. 6A-6C. The features 60a through 60d can be similar to the first features 10a and the second features 10b described in connection with FIGS. 1A-1C, and elsewhere in the disclosure.

As illustrated in FIGS. 6A and 6C, the first feature 60a, the second feature 60b, the third feature 60c, and the fourth feature 60d, and the substrate 610 form a monocrystal. At least one of the features 60a through 60d can comprise a p-i-n junction by doping the monocrystal with one or more dopant species. The p-i-n junction illustrated in FIGS. 6A and 6C is formed in the normal direction. This is similar to the device 10 illustrated in FIGS. 1A and 1B, and the device 40 illustrated in FIG. 4. Alternatively, the device 60 can comprise a p-i-n junction formed conformally, similar to the device 20 illustrated in FIGS. 2A and 2B and the device 30 illustrated in FIGS. 3A and 3B. It is understood that at least one of the features 60a through 60d can form a p-i-n junction, alone or with the substrate, or can include an intrinsic semiconductor or a metal semiconductor junction.

As illustrated in FIG. 6A, the features 60a, 60b, 60c and 60d can comprise a heavily doped semiconductor layer 621, and a lightly doped semiconductor layer 623. The heavily doped semiconductor layer 621 can be a p type or an n-type. The lightly doped semiconductor layer 623 can be of the opposite type from the heavily doped semiconductor layer 621. The heavily doped semiconductor layer 621 can be a p-type or an n-type. The heavily doped semiconductor layer 621 can be disposed on the lightly doped semiconductor layer 623. The layers 621 and 623 form a p-n junction. The substrate 610 can comprise an intrinsic semiconductor layer 624. The lightly doped semiconductor layer 623 can be disposed on the intrinsic semiconductor layer 624. The layers 621, 623 and 624 can form a monocrystal, i.e. the crystal lattice is continuous and unbroken, with no grain boundary between the features and the layer 624 in the substrate. The compositions of features 60a, 60b, 60c and 60d can be different, depending on the desired function of the device. The heights of the features 60a, 60b, 60c and 60d can be the same or different.

At the bottom of the intrinsic semiconductor layer 624, there are charge carrier collectors 630, 640, 650 and 660, located underneath the features 60a, 60b, 60c and 60d, respectively. Any one of the charge carrier collectors 630, 640, 650 and 660 can be similar to either one of the charge carriers 530 and 540 described in connection with FIGS. 5A and 5B. See FIG. 6B. The charge carrier collector 620 discussed below is not shown in FIG. 6B.

The charge carrier collectors 630, 640, 650 and 660 are separate or otherwise substantially electrically insulated from each other. Merely by way of example, the space between the charge carrier collectors 630, 640, 650 and 660 can be filled with or comprise the intrinsic semiconductor 624. Few charge carriers generated in the features 60a, 60b, 60c and 60d reach or are collected by a charge carrier collector other than the one underneath it. This configuration can allow the detection/measurement of the charge carriers generated in one of the features that is substantially independent from the detection/measurement of the charge carriers generated in another feature in the same device. The charge carrier collectors 630, 640, 650 and 660 can be substantially electrically insulated from the ambient by treating a surface thereof that is otherwise exposed to the ambient. The insulation can be achieved by coating or covering the otherwise exposed surface with a layer of an electrically insulating material. As illustrated in FIG. 6A, the substrate 610 can comprise an electrically insulating layer 625 that covers the otherwise exposed surfaces of the charge carrier collector 630, 640, 650 and 660. The electrically insulating layer 625 can, but does not need to form a monocrystal with the intrinsic semiconductor layer 624. The layer 625 can also provide physical support for the device 60. The layer 625 can be a thin coating that does not provide much physical support for the device 60.

Although not shown in FIG. 6A or 6C, the charge carrier collectors 630, 640, 650 and 660 can be connected to a detection/measurement circuitry via, e.g., a conductive wire, or the like. According to an embodiment illustrated in FIG. 6C, charge carriers from at least two of the charge carrier collectors 630, 640, 650 and 660 can be pooled together for detection/measurement. Merely by way of example, the features 60a and 60c have the same composition and configuration such that both are operable to selectively absorb the first portion of the radiation incident on the receiving area of the device. The charge carriers generated in 60a and 60c can move to and accumulate on charge carrier collectors 630 and 650, respectively. The charge carriers can be transferred from their respective charge carrier collectors 630 and 650 via, e.g., conductive wires 670a and 670c, and pooled together for detection/measurement. Likewise, the features 60d and 60d can have the same composition and configuration such that both are operable to selectively absorb the second portion of the radiation incident on the receiving area of the device. The charge carriers generated in 60b and 60d can move to and accumulate on charge carrier collectors 640 and 660, respectively. The charge carriers can be transferred from their respective charge carrier collectors 640 and 660 via, e.g., conductive wires 670b and 670d, and pooled together for detection/measurement. As another example, charge carriers generated in 60a, 60b, 60c and 60d can move to and accumulate on charge carrier collectors 630, 640, 650 and 660, respectively. The charge carriers can be transferred from their respective charge carrier collectors 630, 640, 650 and 660 via, e.g., conductive wires 670a, 670b, 670c, and 670d, for detection/measurement separate/independent from each other.

The device 60 can comprise a corresponding charge carrier collector 620 that can collect the charge carriers of the opposite charge from those collected by one of the charge carrier collectors 630, 640, 650 and 660. According to the embodiment illustrated in FIG. 6A, the features 60a, 60b, 60c and 60d can share the same charge carrier collector 620. Because the charge carrier collectors 630, 640, 650 and 660 are separate or otherwise substantially electrically insulated from each other, the configuration of the corresponding charge carrier collector 620 illustrated in FIG. 6A does not compromise the capacity of the device to independently detecting/measuring the charge carriers generated in the features 60a, 60b, 60c and 60d. To detect/measure the charge carriers generated in the features 60a, 60b, 60c and 60d, the corresponding charge carrier collector 620 and the charge carrier collectors 630, 640, 650 and 660 are connected to a detection/measurement circuitry, respectively. The charge carrier collector 620 can be a substantially continuously conductive layer. According to an embodiment, the charge carrier collector 620 located underneath and operable to receive charge carriers from to one of the features 60a, 60b, 60c and 60d can be separate or otherwise substantially electrically insulated from the charge carrier collector 620 located underneath and operable to receive charge carriers from another of the features 60a, 60b, 60c and 60d, similar to the transparent electrodes 132 illustrated in FIG. 1A.

The device 60 can be configured such that there is little or no dark current (no current when the device is not exposed to radiation, at least some of which can be absorb by the features of the device) when an electrical field is applied to form a drift field.

The configuration of the charge carrier collectors 630, 640, 650 and 660 illustrated in FIGS. 6A-6C is also applicable to a device including a conformal p-i-n junction, similar to the device 20 illustrated in FIGS. 2A and 2B, and the device 30 illustrated in FIGS. 3A and 3B. The device 60 can further can comprise a corresponding charge carrier collector, e.g., one similar to the metal layers 239 illustrated in FIGS. 2A and 2B, or one similar to the metal layers 335 illustrated in FIGS. 3A and 3B. The corresponding charge carrier collector can be associated with (i.e. operable to collect charge carriers from) one of the features 60a, 60b, 60c and 60d, respectively, can be separate or otherwise substantially electrically insulated from the charge carrier collector associated with (i.e. operable to collect charge carriers from) another of the features 60a, 60b, 60c and 60d.

In another exemplary embodiment, the device 60 does not comprise a corresponding charge carrier collector like the corresponding charge carrier collector 620, or one similar to the metal layers 239 illustrated in FIGS. 2A and 2B, or one similar to the metal layers 335 illustrated in FIGS. 3A and 3B. The charge carriers accumulated on any one of charge carrier collectors 630, 640, 650 and 660 can be detected/measured when an electrical field is applied.

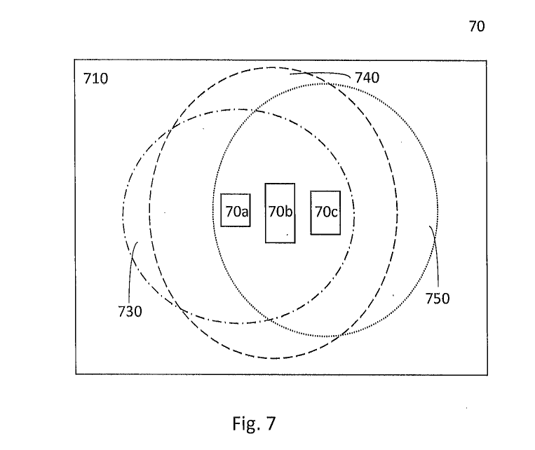

FIG. 7 shows a top view of a device 70 according to one embodiment. A first feature 70a, a second feature 70b, and a third feature 70c of a substrate 710 are illustrated. The device 70, however, can comprise more or fewer first features, or more or fewer second features, or more or fewer third features; the device can comprise one or more other features that can selectively absorb one or more portions of the radiation incident on the receiving area of the device. The arrangement of the first feature 70a, the second features 70b, and the third feature 70c, including the orientations, the relative locations, can be different from that shown in FIG. 7. The first feature 70a, the second feature 70b, and the third feature 70c can be similar to the first features 10a and the second features 10b described in connection with FIGS. 1A-1C, and elsewhere in the disclosure. Although not shown in FIG. 7, the device 70 can comprise one or more charge carrier collectors as described elsewhere in the disclosure, e.g., those described in connection with FIGS. 5A-6C.

As illustrated in FIG. 7, the first feature 70a has a first surrounding area 730 (illustrated by the dash-dotted line), the second feature 70b has a second surrounding area 740 (illustrated by the dashed line), and the third feature 70c (illustrated by the dotted line) has a third surrounding area 750. The first feature 70a can selectively absorb at least 30%, or at least 40%, or at least 50%, or at least 60%, or at least 70%, or at least 80%, or at least 90% of a first portion of the radiation (whose wavelengths are within a first range) in the first surrounding area 730. The second feature 70b can selectively absorb at least 30%, or at least 40%, or at least 50%, or at least 60%, or at least 70%, or at least 80%, or at least 90% of a second portion of the radiation (whose wavelengths are within a second range) in the second surrounding area 740. The third feature can selectively absorb at least 30%, or at least 40%, or at least 50%, or at least 60%, or at least 70%, or at least 80%, or at least 90% of a third portion of the radiation (whose wavelengths are within a third range) in the third surrounding area 750.

According to an embodiment, the first feature 70a and the second feature 70b are positioned on the substrate such that the first surrounding area 730 and the second surrounding area 740 overlap by at least 30%, or at least 40%, or at least 50%, or at least 60%, or at least 70%, or at least 80%, or at least 90% of the smaller of the first surrounding area 730 and the second surrounding area 740.

According to an embodiment, the first feature 70a and the third feature 70c are positioned on the substrate such that the first surrounding area 730 and the third surrounding area 750 overlap by at least 30%, or at least 40%, or at least 50%, or at least 60%, or at least 70%, or at least 80%, or at least 90% of the smaller of the first surrounding area 730 and the third surrounding area 750.

According to an embodiment, the second feature 70b and the third feature 70c are positioned on the substrate such that the second surrounding area 740 and the third surrounding area 750 overlap by at least 30%, or at least 40%, or at least 50%, or at least 60%, or at least 70%, or at least 80%, or at least 90% of the smaller of the second surrounding area 740 and the third surrounding area 750.

According to an embodiment, the first feature 70a, the second feature 70b, and the third feature 70c are positioned on the substrate such that the first surrounding area 730, the second surrounding area 740, and the third surrounding area 750 overlap by at least 30%, or at least 40%, or at least 50%, or at least 60%, or at least 70%, or at least 80%, or at least 90% of the smallest of the first surrounding area 730, the second surrounding area 740, and the third surrounding area 750.

Although the devices illustrated in the drawings comprise p-i-n junctions, a device disclosed herein can comprise at least one first feature and at least one second feature, wherein at least one of the at least one first feature and the at least one second feature has a p-n junction.

The device disclosed herein can further comprise at least one layer of an oxide functional to passivate a surface of the device, e.g., a surface of the features or the substrate. The passivating layer can comprise at least one material selected from the group consisting of HfO₂, SiO₂, Al₂O₃, or the like.

The device disclosed herein can be fabricated using a lithography technique, e.g., photolithrograph or e-beam lithography. The fabrication procedure can further include at least one of the techniques including, for example, atomic layer deposition (ALD) and chemical vapor deposition (CVD), thermal evaporation, e-beam evaporation, and sputtering, dry etching, plasma ashing and dissolution in a suitable solvent, chemical mechanical polishing (CMP), spin-coating, wet etching with a suitable metal etchant, ion implantation, annealing, or the like, or a combination thereof.

FIG. 8 shows exemplary features having a cross-section of a cross, a circle, an L shape. The width of a feature is the largest dimension in the thickness direction, the transverse dimension is the largest dimension in the transverse direction, and the aspect ratio of the feature is the ratio of the transverse dimension to the width.

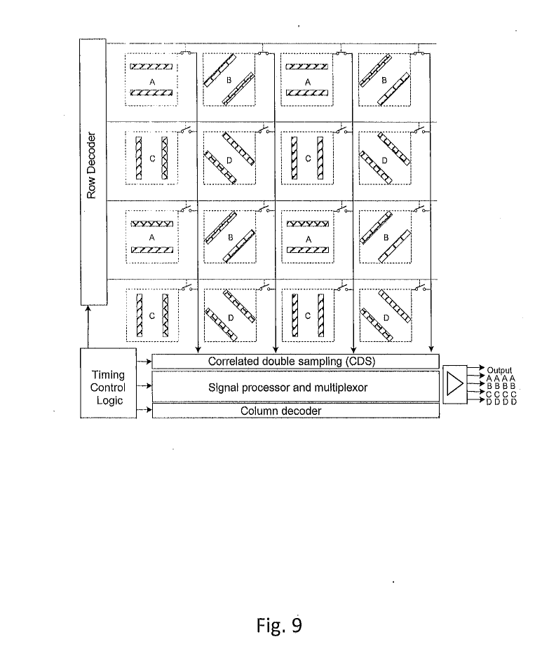

According to one embodiment as shown in FIG. 9, the device disclosed herein can be integrated with electronic circuitry into a radiation detector array. The electronic circuitry can include address decoders in both directions of the detector array, a correlated double sampling circuit (CDS), a signal processor, a multiplexor. The electronic circuitry is functional to detect the electrical signal converted by the features from at least some of the radiation impinged thereon. The electric circuitry can be further functional to calculate an interpolation of electrical signals from the features. Other function of the electronic circuitry can include a gain adjustment, a calculation of Stokes parameters. Merely by way of example, features configured to selectively absorb different portions of the radiation can be arranged into groups. For example, in FIG. 9, first features A, second features B, third features C, and fourth features D are configured to selectively absorb a first portion, a second portion, a third portion, and a fourth portion of the radiation, respectively, and are arranged into four groups. The first portion, the second portion, the third portion, and the fourth portion of the radiation are defined by, e.g., their wavelengths, wherein the wavelengths of at least two of these portions of the radiation are within two different ranges.

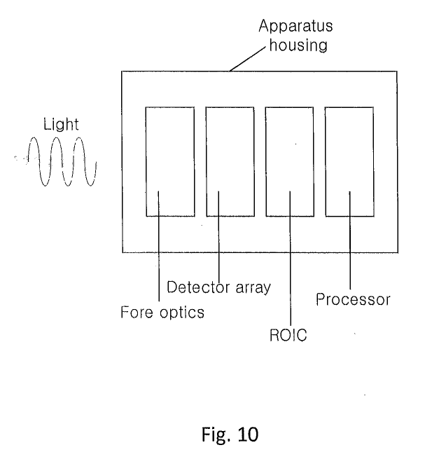

The device disclosed herein can also be used as fore optics in a light detector apparatus as shown in the schematic in FIG. 10. The device can be incorporated into a system such as, for example, a camera, a video camera, a microscope, a satellite, an image sensor, a land vehicle (e.g., a car, a truck, a motorcycle), a water vehicle (e.g., a ship), an air vehicle (e.g., an unmanned air vehicle, an aircraft), a balloon, and an imaging device. The device can detect/measure radiation based on wavelengths, linear polarization, or both.

According to an embodiment, a method of detecting different portions of radiation using a device disclosed herein comprises obtaining the device, exposing the device to the radiation, and detecting the portions of the radiation whose wavelengths are within the ranges of interest.

The foregoing detailed description has set forth various embodiments of the devices and/or processes by the use of diagrams, flowcharts, and/or examples. Insofar as such diagrams, flowcharts, and/or examples contain one or more functions and/or operations, it will be understood by those within the art that each function and/or operation within such diagrams, flowcharts, or examples can be implemented, individually and/or collectively, by a wide range of hardware, software, firmware, or virtually any combination thereof.

Those skilled in the art will recognize that it is common within the art to describe devices and/or processes in the fashion set forth herein, and thereafter use engineering practices to integrate such described devices and/or processes into data processing systems. That is, at least a part of the devices and/or processes described herein can be integrated into a data processing system via a reasonable amount of experimentation.

The subject matter described herein sometimes illustrates different components contained within, or connected with, other components. It is to be understood that such depicted architectures are merely exemplary, and that in fact many other architectures can be implemented which achieve the same functionality. In a conceptual sense, any arrangement of components to achieve the same functionality is effectively “associated” such that the desired functionality is achieved. Hence, any two components herein combined to achieve a particular functionality can be seen as “associated with” each other such that the desired functionality is achieved, irrespective of architectures or intermediate components.

With respect to the use of substantially any plural and/or singular terms herein, those having skill in the art can translate from the plural to the singular and/or from the singular to the plural as is appropriate to the context and/or application. The various singular/plural permutations may be expressly set forth herein for sake of clarity.

All references, including but not limited to patents, patent applications, and non-patent literature are hereby incorporated by reference herein in their entirety.

While various aspects and embodiments have been disclosed herein, other aspects and embodiments will be apparent to those skilled in the art. The various aspects and embodiments disclosed herein are for purposes of illustration and are not intended to be limiting, with the true scope and spirit being indicated by the following Claims.

What is claimed is:

1. A device comprising:
at least one first feature, wherein the at least one first feature extends substantially perpendicularly from a substrate, the at least one first feature is operable to selectively absorb the first portion of radiation, the wavelengths of the first portion of the radiation are within a first range; and
at least one second feature, wherein the at least one second feature extends substantially perpendicularly from the substrate, the at least one second feature is operable to selectively absorb the second portion of the radiation, the wavelengths of the second portion of the radiation are within a second range,
wherein the first range is different from the second range,
wherein the at least one first feature and the at least one second feature are positioned on the substrate such that at least a first percentage of the first portion of the radiation incident on the receiving area is absorbed by the at least one first feature, and at least a second percentage of the second portion of the radiation incident on the receiving area is absorbed by the at least one second feature, and
wherein the first percentage or the second percentage is at least 50%.

2. The device of claim 1, wherein the first range of wavelengths or the second range of wavelengths is 450-495 nm, 495-570 nm, 570-590 nm, or 620-740 nm.

3. The device of claim 1, wherein the incident direction of the radiation is substantially perpendicular to the substrate.

4. The device of claim 1, wherein the first percentage or the second percentage is at least 60%.

5. The device of claim 1 comprising multiple first features or multiple second features.

6. The device of claim 5, wherein at least two of the multiple first features have a same orientation, or at least two of the multiple second features have a same orientation.

7. The device of claim 5, wherein at least some adjacent first features of the multiple first features are equally spaced from each other, or at least some adjacent second features of the multiple second features are equally spaced from each other.

8. The device of claim 1, wherein
the at least one first feature has a first width and a first transverse dimension; and
the at least one second feature has a second width and a second transverse dimension.

9. The device of claim 8, wherein the first transverse dimension or the second transverse dimension is approximately 100 nm, approximately 80 nm, or approximately 60 nm.

10. The device of claim 8, wherein the first width or the second width is approximately 100 nm, approximately 80 nm, or approximately 60 nm.

11. The device of claim 1, wherein the aspect ratio of the at least one first feature or the aspect ratio of the at least one second feature is less than 5, or less than 3.

12. The device of claim 1, wherein the substrate, the at least one first feature, or the at least one second feature comprises at least one material selected from the group consisting of silicon, germanium, boron, tellurium, selenium, tin, a III-V group compound semiconductor, and a II-VI group compound semiconductor.

13. The device of claim 1, wherein
the at least one first feature is operable to react to the first portion of the radiation by converting at least a part of it to a first signal; or
the at least one second feature is operable to react to the second portion of the radiation by converting at least a part of it to a second signal.

14. The device of claim 13, wherein the first signal or the second signal is an electrical signal.

15. The device of claim 14, wherein the substrate comprises electrical components configured to detect the electrical signal.

16. The device of claim 1, wherein
at least a part of the substrate, the at least one first feature, and the at least one second feature form a monocrystal;
the substrate comprises a first charge carrier collector and a second charge carrier collector;
the first charge carrier collector configured to collect at least some charge carriers generated in the at least one first feature by absorbing the first portion of the radiation; and
the second charge carrier collector configured to collect at least some charge carriers generated in the at least one second feature by absorbing the second portion of the radiation.

17. The device of claim 16, wherein the first charge carrier collector and the second charge carrier collector are electrically insulated to each other.

18. The device of claim 16, wherein
the first charge carrier collector is substantially parallel to the substrate, or slightly larger than the cross-section of the at least one first feature, or
the second charge carrier collector is substantially parallel to the substrate, or slightly larger than the cross-section of the at least one second feature.

19. The device of claim 1, wherein
the at least one first feature or the at least one second feature comprises an intrinsic semiconductor layer or a first lightly doped semiconductor layer, and a heavily doped semiconductor layer;
the substrate comprises a second lightly doped semiconductor layer;
the second lightly doped semiconductor layer is an opposite type from the heavily doped semiconductor layer;
intrinsic semiconductor layer or a first lightly doped semiconductor layer is disposed on the second lightly doped semiconductor layer;
the heavily doped semiconductor layer is disposed on the intrinsic semiconductor layer or the first lightly doped semiconductor layer; and
the heavily doped semiconductor layer, the intrinsic layer or the first lightly doped semiconductor layer, and the second lightly doped semiconductor layer form a p-i-n junction.

20. The device of claim 1, wherein
the at least one first feature or the at least one second feature comprises a core of intrinsic semiconductor layer or lightly doped semiconductor layer, and a shell of heavily doped semiconductor;
the substrate comprises a lightly doped semiconductor layer;
the lightly doped semiconductor layer is an opposite type from the shell;
the core is disposed on the lightly doped semiconductor layer;
the shell is conformally disposed over the core; and
the shell, the core, and the lightly doped semiconductor layer form a p-i-n junction.

21. The device of claim 1, wherein
the at least one first feature or the at least one second feature comprises a core of lightly doped semiconductor, an intermediate shell of intrinsic semiconductor, and an outer shell of doped semiconductor;
the intermediate shell is conformally disposed over the core;
the outer shell is conformally disposed over the intermediate shell;
the outer shell is of an opposite type from the core; and
the outer shell, the intermediate shell, and the core form the p-i-n junction.

22. The device of claim 1, wherein
the at least one first feature or the at least one second feature comprises a first heavily doped semiconductor layer, a lightly doped semiconductor layer or intrinsic semiconductor layer, and a second heavily doped layer;
the first heavily doped semiconductor layer is disposed on the lightly doped semiconductor layer or intrinsic semiconductor layer;
the lightly doped semiconductor layer or intrinsic semiconductor layer is disposed on the second heavily doped layer;
the first heavily doped layer is of an opposite type from the second heavily doped layer; and
the first heavily doped layer, the lightly doped semiconductor layer or intrinsic semiconductor layer, and the second heavily doped layer form the p-i-n junction.

23. The device of claim 1, further comprising a first transparent electrode disposed on and electrically connected to the at least one first feature.

24. The device of claim 23, further comprising a second transparent electrode disposed on and electrically connected to the at least one second feature.

25. The device of claim 24, wherein the first and second transparent electrodes are electrically insulated from each other.

26. The device of claim 1, further comprising a reflective material deposited on an area of the substrate between the at least one first feature and the at least one second feature.

27. The device of claim 1, further comprising a cladding layer enclosing at least a part of the at least one first feature or at least a part of the at least one second feature.

28. The device of claim 27, wherein the cladding layer comprises at least one material selected from the group consisting of plasma enhanced Si₃N₄, plasma enhanced SiO₂, and SiO₂.

29. The device of claim 28, wherein the cladding layer is configured to provide a graded refractive index such that a refractive index of the enclosed first feature is higher than that of the cladding layer, or a refractive index of the enclosed second feature is higher than that of the cladding layer.

30. The device of claim 1, further comprising at least one third feature, wherein the at least one third feature extends substantially perpendicularly from the substrate, the at least one third feature is operable to selectively absorb a third portion of the radiation, the wavelengths of the third portion of the radiation are within a third range,
wherein the third range is different from the first range or the second range,
wherein at least one third feature is positioned on the substrate such that at least a third percentage of the third portion of the radiation incident on the receiving area is absorbed by the at least one third feature, and
wherein the third percentage is at least 50%.

31. The device of claim 30, wherein the at least one third feature is operable to react to the third portion of the radiation by converting at least a part of it to a third signal.

32. A system comprising the device of claim 1 and electronic circuitry functional to detect an electrical signal.

33. The system of claim 32, wherein the electronic circuitry is further functional to calculate an interpolation from the at least one first feature or from the at least one second feature, adjust a gain and/or calculate Stokes' parameters.

34. The system of claim 32, wherein the system comprises at least one system selected from the group consisting of an aircraft, a land vehicle, a water vehicle, an air vehicle, a balloon, an imaging device, a camera, a video camera, a microscope, a satellite, and an image sensor.

35. A device comprising
at least one first feature, wherein the at least one first feature extends substantially perpendicularly from a substrate, the at least one first feature has a first surrounding area, the first feature is operable to selectively absorb at least a first percentage of a first portion of radiation incident on a receiving area of the device, the wavelengths of the first portion of the radiation are within a first range; and
at least one second feature, wherein the at least one second feature extends substantially perpendicularly from the substrate, the at least one second feature has a second surrounding area, the second feature is operable to selectively absorb at least a second percentage of a second portion of the radiation in the second surrounding area, the wavelengths of the second portion of the radiation are within a second range,
wherein the first range is different from the second range,
wherein the at least one first feature and the at least one second feature are positioned on the substrate such that the first surrounding area and the second surrounding area overlap by at least 50% of the smaller of the first surrounding area and the second surrounding area, and
wherein the first percentage or the second percentage is at least 50%.

36. The device of claim 35, wherein the first percentage or the second percentage is at least 60%.

37. The device of claim 36, wherein the first range of wavelengths or the second range of wavelengths is 450-495 nm, 495-570 nm, 570-590 nm, or 620-740 nm.

38. The device of claim 36, wherein
the at least one first feature has a first width and a first transverse dimension; and
the at least one second feature has a second width and a second transverse dimension.

39. The device of claim 38, wherein the first transverse dimension or the second transverse dimension is approximately 100 nm, approximately 80 nm, or approximately 60 nm.

40. The device of claim 38, wherein the first width or the second width is approximately 100 nm, approximately 80 nm, or approximately 60 nm.

41. The device of claim 36, wherein the aspect ratio of the at least one first feature or the aspect ratio of the at least one second feature is less than 5, or less than 3.

42. The device of claim 36, wherein
at least a part of the substrate, the at least one first feature, and the at least one second feature form a monocrystal,
the substrate comprises a first charge carrier collector and a second charge carrier collector,
the first charge carrier collector is configured to collect at least some charge carriers generated in the at least one first feature by absorbing the first portion of the radiation,
the second charge carrier collector is configured to collect at least some charge carriers generated in the at least one second feature by absorbing the second portion of the radiation, and
the first charge carrier collector and the second charge carrier collector are electrically insulated from each other.

43. The device of claim 42, wherein the first charge carrier collector is substantially parallel to the substrate, or slightly larger than the cross-section of the at least one first feature, or wherein the second charge carrier collector is substantially parallel to the substrate, or slightly larger than the cross-section of the at least one second feature.

44. The device of claim 36, wherein the substrate, the at least one first feature, or the at least one second feature comprises at least one material selected from the group consisting of silicon, germanium, boron, tellurium, selenium, tin, a III-V group compound semiconductor, and a II-VI group compound semiconductor.

45. A system comprising the device of claim 36 and electronic circuitry functional to detect an electrical signal.

46. The system of claim 45, wherein the system comprises at least one system selected from the group consisting of an aircraft, a land vehicle, a water vehicle, an air vehicle, a balloon, an imaging device, a camera, a video camera, a microscope, a satellite, and an image sensor.

47. A method of detecting a first portion and a second portion of radiation, comprising
obtaining the device of claim 1,
exposing the device to the radiation, and
detecting the first portion and the second portion of the radiation,
wherein the wavelengths of the first portion of the radiation are within a first range, the wavelengths of the second portion of the radiation are within a second range, and the first range and the second range are different.

48. A device comprising:
at least one first feature extending substantially perpendicularly to a substrate, the at least one first feature configured to selectively absorb a first portion of radiation within a first range of wavelength; and
at least one second feature extending substantially perpendicular to the substrate, the at least one second feature configured to selectively absorb a second portion of the radiation within a first range of wavelength; wherein
the first range and the second range are different, and
the first feature and the second feature are positioned in proximity and configured such that the at least one first feature is operable to substantially absorb the first portion of the radiation in a receiving area of the device, and the at least one second feature is operable to substantially absorb the second portion of the radiation in the receiving area of the device.
